(19) United States
(12) Patent Application Publication
(10) Pub. No.: US 2012/0000385 A1
(43) Pub. Date: Jan. 5, 2012

(54) LITHOGRAPHIC PRINTING PLATE MATERIAL AND LITHOGRAPHIC PRINTING PLATE

(75) Inventor: Takahiro Mori, Tokyo (JP)

(73) Assignee: KONICA MINOLTA MEDICAL & GRAPHIC, INC., Hino-shi, Tokyo (JP)

(21) Appl. No.: 13/256,907

(22) PCT Filed: Jan. 14, 2010
(86) PCT No.: PCT/JP2010/050329

§ 371 Date: Sep. 15, 2011

(30) Foreign Application Priority Data
Mar. 19, 2009 (JP) 2009-067689

(51) Int. Cl. B41N 1/04; G03F 7/038; G03F 7/09

(52) U.S. Cl. 101/454; 430/278.1

(57) ABSTRACT

Disclosed is a negative type lithographic printing plate material comprising a surface-roughened and anodically oxidized aluminum substrate and a photosensitive layer provided thereon, characterized in that: said photosensitive layer comprises a novolac resin, which contains a binder resin (a), a crosslinking agent (b), an infrared-absorbing agent (c) and an acid-generating agent (d), and in which the binder resin (a) contains 20-100 mass % inclusive of a phenol part expressed in ratio by mass, and a polyvinylphenol polymer; the content ratio of the novolac resin to the polyvinylphenol polymer (the mass of the novolac resin:the mass of the polyvinylphenol polymer) is 7:3 to 3:7; and the ratio by mass [(b)/(a)] is 0.25 to 0.50 inclusive. After the lithographic printing plate material is subjected to plate-making to give a lithographic printing plate, an image part thereof has a high solvent resistance and an excellent fraction resistance and the lithographic printing plate can be subjected to near infrared laser exposure. Also disclosed is the lithographic printing plate.

### TECHNICAL FIELD

The present invention relates to a planography (lithographic printing) plate material having a negative light sensitive layer for use in a so-called computer-to-plate (hereafter, referred to as CTP) system, more specifically to a planography plate material which can form an image with exposure of a near-infrared laser and is excellent in solvent resistance and wear resistance at image portions after production of a printing plate, and to a planography plate.

### BACKGROUND ART

With regard to planography plate materials of a so-called negative type in which exposed portions become insoluble upon irradiation of active light, well-known techniques form image portions by causing photo-polymerization or photo-cross-linking at portions irradiated with active light (for example, refer to Patent documents 1 and 2). Further, some techniques disclose to conduct infrared exposure for a photosensitive material that contains a binder (novolak resin), a cross linking agent (resole resin, melamine resin) which cross-links with the binder under existence of an acid, an infrared absorption agent, and an acid generating agent, in such a way that exposed potions are insolubilize for alkali (for example, refer to Patent documents 3, 4 and 5).

Although planography plate materials employing these techniques have a certain degree of printing resistance, the cross-linking of image portions is insufficient and the image portions are inferior in solvent resistance and wear resistance. Therefore, the resistance for various chemicals and cleaners used at the time of printing is insufficient. Accordingly, in the case where a cleaner containing a lot of solvent is used or a cleaner containing an abrasive compound is used, printing resistance may remarkably deteriorate. In such a case, countermeasures are taken such that baking treatment is conducted after development so as to advance cross-linking of image potions. However, planography plate materials capable of providing planography plates having sufficient solvent resistance and wear resistance without baking treatment.

### RELATED ART DOCUMENT

### Patent Document

Patent document 1: Japanese Patent Publication No. 52-7364, Official report
Patent document 2: Japanese Patent Publication No. 52-3216, Official report
Patent document 3: U.S. Pat. No. 5,340,699, specification
Patent document 4: U.S. Pat. No. 5,763,134, specification
Patent document 5: Japanese Unexamined Patent Publication No. 11-143075, official report

### SUMMARY OF THE INVENTION

### Problem to be Solved by the Invention

The present invention is achieved in view of the above-mentioned problems, and an object of the present invention is to provide a negative type planography plate material which is excellent in solvent resistance and wear resistance at image portions after being made into a planography plate and allows near-infrared laser exposure, and a planography plate.

### Means for Solving the Problem

The above-mentioned object of the present invention is attained by the following structures.

1. A planography plate material, comprises:

an aluminum support subjected to roughening treatment and anodizing treatment; and

a photosensitive layer;

wherein the photosensitive layer contains

(a) a binder resin;

(b) a cross-linking agent;

(c) an infrared absorption agent

(d) an acid generating agent; and

the planography plate material is characterized in that the binder resin (a) contains a novolak resin containing a phenol component in an amount of 20% by weight or more and 100% by weight or less by weight ratio and a polyvinyl phenol polymer, a content rate between the novolak resin and the polyvinyl phenol polymer (a weight of the novolak resin:a weight of the polyvinyl phenol polymer) is 7:3 to 3:7, a weight ratio (b/a) of the cross-linking agent (b) to the binder resin (a) is 0.25 or more and 0.5 or less.

2. The planography plate material described in 1, is characterized in that the cross-linking agent (b) contains a melamine resin.
3. The planography plate material described in 1 or 2, is characterized in that the acid generating agent contains a triazine compound.
4. The planography plate material described in any one of 1 to 3, characterized in that a surface roughness Ra (μm) of the aluminum support and a dried coated weight (g/m²) of the photosensitive layer satisfy Formula (1).

Dried coated weight of a photosensitive layer−Ra≧1.0 Formula (1)

5. A planography plate obtained by subjecting the planography plate material described in any one of 1 to 4 to imagewise exposure, heat treatment, development treatment, is characterized in that a plate surface reaching temperature is 130° C. or more and 155° C. or less.
6. The planography plate described in 5, is characterized in that a heating device used for the heat treatment is a device which heats while conveying the planography plate material, the heating device has a plurality of heating zones a temperature of each of which can be set independently of others, and the set temperature of a heating zone through which the planography plate material passes lastly is lower than a heating processing condition of the previous heating zones.
7. The planography plate described in 6, is characterized in that the set temperature of a heating zone through which the planography plate material passes lastly is lower 5° C. or more than the highest setting temperature of the previous heating zones.

### Effect of the Invention

According to the present invention, it becomes possible to provide a negative type planography plate material which is excellent in solvent resistance and wear resistance at image portions after being made into a planography plate and allows near-infrared laser exposure, and a planography plate.

### EMBODIMENT FOR CARRYING OUT THE INVENTION

A planography plate material of the present invention, comprises:

an aluminum support subjected to roughening treatment and anodizing treatment; and

a photosensitive layer;

wherein the photosensitive layer contains

(a) a binder resin;

(b) a cross-linking agent;

(c) an infrared absorption agent

(d) an acid generating agent; and

the planography plate material is characterized in that the binder resin (a) contains a novolak resin containing a phenol component in an amount of 20% by weight or more and 100% by weight or less by weight ratio and a polyvinyl phenol polymer, a content rate between the novolak resin and the polyvinyl phenol polymer (a weight of the novolak resin:a weight of the polyvinyl phenol polymer) is 7:3 to 3:7, a weight ratio (b/a) of the cross-linking agent (b) to the binder resin (a) is 0.25 or more and 0.5 or less.

In the present invention, the above specific structure of the binder and the above specific range of a ratio of the binder and the cross-linking agent makes it possible to obtain the planography plate material excellent in solvent resistance, wear resistance and printing resistance.

Hereafter, although the present invention and structural elements will be explained in detail, first, the featured structural elements in the present invention will be explained, and then, various techniques usable in combination in the typical embodiments of the planography plate material of the present invention will be explained.

### <Support>

As the aluminum support of the invention for a planographic printing plate material, an aluminum plate is used. The aluminum plate is a pure aluminum plate or an aluminum alloy plate.

As the aluminum alloy, there can be used various ones including an alloy of aluminum and a metal such as silicon, copper, manganese, magnesium, chromium, zinc, lead, bismuth, nickel, titanium, sodium or iron. Further, an aluminum plate manufactured by rolling can be used. A regenerated aluminum plate obtained by rolling aluminum regenerated from scrapped or recycled materials, which has recently spread, can be also used.

In the invention, the aluminum plate preferably contains Mg in amount of from 0.1 to 0.4% by weight in printing durability in view of contamination resistance. That the aluminum plate contains Mg implies that the aluminum plate contains Mg in the element composition.

An aluminum plate having a concavo-convex surface formed by transferring the concavo-convex pattern on the surface may be used as the aluminum plate in the invention, or a concavo-convex surface may be formed by transferring the concavo-convex pattern on the surface of an aluminum plate. A method of forming concavo-convex according to rolling processing is not specifically limited but the rolling processing is preferably carried out employing a pressure roll. An aluminum plate having a concavo-convex surface, which is formed by transfer or pack rolling in the final rolling process, can be used.

Particularly is preferred a method which brings a mill roll having a concavo-convex pattern into contact with the aluminum plate surface so as to transfer the concavo-convex pattern in combination with cold rolling for adjusting to a final plate thickness or with finish rolling for obtaining a final surface configuration after adjusting to a final plate thickness, whereby a concavo-convex pattern is formed on the aluminum plate surface. For example, a method disclosed in Japanese Patent O.P.I. Publication No. 6-262203 can be suitably used.

It is especially preferred that the transfer is carried out in a conventional final cold rolling of an aluminum plate. It is preferred that rolling for the transfer is carried out through one to three passes, each of which is carried out at a roll reduction of 3 to 8%.

In the invention, as a method of obtaining a transfer roll having a concavo-convex surface used in transfer of a concavo-convex pattern, a method is used which blows specific alumina particles, and an air blasting method is preferred.

The air pressure in the air blasting method is preferably from 9.8×10⁴ to 9.8×10⁵ Pa, and more preferably from 1.96×10⁵ to 4.90×10⁵ Pa.

Grit materials used in the air blasting method are not specifically limited as long as they are alumina particles having a specific particle size. When hard alumina particles having acute protrusions are used as the grit materials, a deep and uniform concavo-convex pattern is likely to be formed on the surface of a transfer roll.

The average particle size of the alumina particles is from 50 to 150 μm, preferably from 60 to 130 μm, and more preferably from 70 to 90 μm. Since the alumina particles having the above average particle size range provide a transfer roll having a sufficiently large surface roughness, such a transfer roll provides a sufficiently large surface roughness to an aluminum plate, and can form a large number of pits.

Jetting in the air blasting method is carried out preferably two to five times, and more preferably two times. In the two jetting, protrusions in the non-uniform concavo-convex pattern formed at the first jetting can be ground at the second jetting, and therefore, when a concavo-convex pattern is formed on an aluminum plate surface employing a transfer roll obtained as above, deep recesses partially located on the aluminum plate surface are difficult to form. As a result, developability (sensitivity) of a planographic printing plate material is excellent.

The jetting angle with respect to a jetted surface (roll surface) in the air blasting method is preferably from 60 to 120°, and more preferably from 80 to 100°.

Before plate processing as described later carried out after the air blasting processing, the roll surface is preferably grained until the average surface roughness (Ra) obtained after the air blasting processing is reduced by 10 to 40%. Graining is preferably carried out employing a sand paper, a grinding stone or a buff. Graining can form protrusions with uniform height on the transfer roll surface. When a concavo-convex pattern is formed on an aluminum plate surface employing a transfer roll obtained as above, deep recesses partially located on the aluminum plate surface are difficult to form. As a result, developability (sensitivity) of a planographic printing plate material is excellent.

The average surface roughness (Ra) of the transfer roll is preferably from 0.4 to 1.0 μm, and more preferably from 0.6 to 0.9 μm. The number of the convexes on the transfer roll surface is preferably from 1000 to 40000/mm², and more preferably from 2000 to 10000/mm². Too less number of the protrusions lowers water retention property of the support of a planographic printing plate material and adhesion of the image formation layer to the support. Lowering of the water retention property tends to cause contamination at dot image portions.

In the invention, a roll made of steel is preferably used. Particularly, a roll manufactured according to cast is preferred. One preferred example of the roll material composition is as follows:

C: 0.07 to 6% by weight; Si: 0.2 to 1% by weight;
Mn: 0.15 to 1% by weight; P: not more than 0.03% by weight; S: not more than 0.03% by weight;
Cr: 2.5 to 12% by weight; Mo: 0.05 to 1.1% by weight; Cu: not more than 0.5% by weight; V: not more than 0.5% by weight; and Residue: Fe and impurities

Materials for the transfer roll include tool steel (SKD), high-speed steel (SKH), high carbon chromium bearing steel (SUJ) and cast steel containing carbon, chromium, molybdenum and vanadium. In order to secure long-term lifetime, a high chromium alloy cast steel containing 10 to 20% by weight of chromium can be used. Particularly, a roll according to a casting process is preferably used. Hardness of a roll after quenching and tempering is preferably from 80 to 100 in terms of Hs. The tempering is carried out at a low temperature. The diameter of the roll is preferably from 200 to 1000 mm, and the surface length of the roll is preferably from 1000 to 4000 mm. It is preferred that the transfer roll having a concavo-convex pattern formed on the surface according to the air blasting method is washed, followed by hardening treatment such as quenching or hard chromium plating, whereby anti-abrasion property is improved and long life-term is secured.

As hardening treatment, hard chromium plating is especially preferred. As the hard chromium plating method, an electroplating method can be used which employs a conventional CrO₃—SO₄ or CrO₃—SO₄-fluoride bath used in industrial chromium plating.

The thickness of a hard chromium plating film is preferably from 3 to 15 μm, and more preferably from 5 to 10 μm. The roll having a plating film with a thickness falling within the above range is difficult to cause film separation in which the plating film is separated from the interface between the roll surface and the film, and improves anti-abrasion property markedly. The thickness of the hard chromium plating film can be controlled by adjusting the plating treatment time.

As methods to preparing a pressure roll having a concavo-convex pattern on the surface, there can be used methods disclosed in Japanese Patent O.P.I. Publication Nos. 60-36195, 2002-251005, 60-203495, 55-74898 and 62-111792.

It is preferred that the aluminum plate with a concavo-convex pattern formed employing a pressure roll having a convex-concavo pattern on the surface has a concavo-convex structure of a pitch from 10 to 100 μm.

In the above aluminum plate, the arithmetic average roughness (Ra) is preferably from 0.4 to 1.5 μm, and more preferably from 0.4 to 0.8 μm. Rmax is preferably from 1 to 6 μm, and more preferably from 2 to 5 μm. RSm is preferably from 5 to 150 μm, and more preferably from 10 to 100 μm. The number of concave portions on the surface is preferably from 200 to 20000/mm².

The aluminum plate in the invention whose surface is formed by transfer so as to have the concavo-convex pattern used in the invention is one in a continuous strip-shaped sheet or plate form. The aluminum plate may be in the form of web, or in the sheet form in which the aluminum plate is cut to the size of a planographic printing plate material shipped as a product.

Since faults on the surface of an aluminum plate have possibility that results in defects of an aluminum support for a planographic printing plate material which is prepared from the aluminum plate, it is necessary to restrain occurrence of the faults as much as possible prior to surface processing whereby the aluminum support for a planographic printing plate material is prepared. Accordingly, when the aluminum plates are transported, they should be in the stable form in which faults are difficult to produce.

The packaging shape of an aluminum web is, for example, as follows. Hard board and felt are placed on an iron pallet. A donut type cardboard plate is provided on both sides of a product. The product is covered with poly tubing. A wooden donut is disposed on the inner periphery of a coil around which the aluminum web is wounded, and a felt on the outer periphery of the coil. The product is tied up with an iron band and a display is carried out on the outermost surface of the product. Polyethylene film can be used as packaging material, and needle felt or hard board as buffering material. The invention is not limited to this as long as stable transport without producing faults is possible, although there are other various packaging shapes.

The thickness of the aluminum plate used invention is from 0.1 mm to 0.6 mm, preferably from 0.15 mm to 0.4 mm, and more preferably from 0.2 mm to 0.3 mm. This thickness can be suitably varied due to the size of a printing press, the size of a planographic printing plate material or user requirements.

Subsequently, surface roughening is carried out. In the invention, in some cases the aluminum plate, after a concavo-convex pattern having been transferred on the surface, is electrolytically surface roughened in an aqueous nitric acid solution, and then in an aqueous hydrochloric acid solution. However, prior to the electrolytically surface roughening, mechanical surface roughening may be carried out.

Though there is no restriction for the mechanical surface roughening method, a brushing roughening method and a honing roughening method are preferable. The brushing roughening method is carried out by rubbing the surface of the support with a rotating brush with a brush hair with a diameter of 0.2 to 0.8 mm, while supplying slurry in which volcanic ash particles with a particle size of 10 to 100 μm are dispersed in water to the surface of the support. The honing roughening method is carried out by ejecting obliquely slurry with pressure applied from nozzles to the surface of the support, the slurry containing volcanic ash particles with a particle size of 10 to 100 μm dispersed in water. A surface roughening can be also carried out by laminating a support surface with a sheet on the surface of which abrading particles with a particle size of from 10 to 100 μm was coated at intervals of 100 to 200 μm and at a density of 2.5×10³ to 1.0×10³/cm², and applying pressure to the sheet to transfer the roughened pattern of the sheet and roughen the surface of the support.

After the support has been roughened mechanically, it is preferably dipped in an acid or an aqueous alkali solution in order to remove abrasives and aluminum dust, etc. which have been embedded in the surface of the support. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, an aqueous alkali solution of for example, sodium hydroxide is preferably used. The dissolution amount of aluminum in the support surface is preferably 0.5 to 5 g/m². After the support has been dipped in the aqueous alkali solution, it is preferable for the support to be dipped in an acid such as phosphoric acid, nitric acid, sulfuric acid and chromic acid, or in a mixed acid thereof, for neutralization.

When electrolytically surface roughening is carried out in an electrolytic solution containing mainly nitric acid, employing alternating current, voltage applied is generally from 1 to 50 V, and preferably from 10 to 30 V. The current density used can be selected from the range from 10 to 200 A/dm², and is preferably from 20 to 100 A/dm². The quantity of electricity can be selected from the range of from 100 to 5000 C/dm², and is preferably 100 to 2000 C/dm². The temperature during the electrolytically surface roughening may be in the range of from 10 to 50° C., and is preferably from 15 to 45° C. The nitric acid concentration in the electrolytic solution is preferably from 0.1% by weight to 5% by weight. The electrolytic solution can contain nitrates, chlorides, amines, aldehydes, phosphoric acid, chromic acid, boric acid, acetic acid, oxalic acid or an aluminum ion, as necessary.

After electrolytically surface roughened is carried out in the electrolytic solution containing mainly nitric acid, it is preferably dipped in an acid or an aqueous alkali solution in order to remove aluminum dust and the like produced in the surface of the aluminum plate. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used. The dissolution amount of aluminum in the plate surface is preferably 0.5-5 g/m². After the plate has been dipped in the aqueous alkali solution, it is preferably dipped in an acid such as phosphoric acid, nitric acid, sulfuric acid and chromic acid, or in a mixed acid thereof, for neutralization.

When electrolytically surface roughening is carried out in an electrolytic solution containing mainly hydrochloric acid, the hydrochloric acid concentration of the electrolytic solution is from 5 to 20 g/L, and preferably from 6 to 15 g/L. The current density is 15 to 120 A/dm², and preferably 20 to 90 A/dm². The quantity of electricity is 400 to 2000 C/dm², and preferably 500 to 1200 C/dm². A frequency of 40 to 150 Hz is preferably employed. Temperature of the electrolytic solution is 10 to 50° C., and preferably 15 to 45° C. The electrolytic solution can contain nitrates, chlorides, amines, aldehydes, phosphoric acid, chromic acid, boric acid, acetic acid, oxalic acid or an aluminum ion, as necessary.

After electrolytically surface roughened is carried out in the electrolytic solution containing mainly hydrochloric acid, it is preferably dipped in an acid or an aqueous alkali solution in order to remove aluminum dust and the like produced in the surface of the aluminum plate. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used. The dissolution amount of aluminum in the plate surface is preferably 0.5-2 g/m². After the plate has been dipped in the aqueous alkali solution, it is preferably dipped in an acid such as phosphoric acid, nitric acid, sulfuric acid and chromic acid, or in a mixed acid thereof; for neutralization.

The surface on a light-sensitive layer side of the aluminum plate obtained above preferably has arithmetic average roughness (Ra) of preferably 0.3 to 0.7 μm, and more preferably 0.4-0.6 μm. The surface roughness can be controlled by an appropriate combination of hydrochloric acid concentration, current density and quantity of electricity in surface roughening.

After the electrolytically surface roughening, anodizing treatment is carried out so as to form an oxidation film on the support surface. The anodizing treatment is carried out by use of an electrolytic solution containing mainly a sulfuric acid or a phosphoric acid. The sulfuric acid concentration in the electrolytic solution is preferably from 5 to 50% by weight, and more preferably from 10 to 35% by weight. The temperature is preferably from 10 to 50° C. Applied voltage is preferably not less than 18V, and more preferably not less than 20V. The current density is preferably from 1 to 30 A/dm². The quantity of electricity is preferably from 20 to 600 C/dm².

The amount of the formed anodization film is preferably from 2 to 6 g/m², and more preferably from 3 to 5 g/m². The amount of the formed anodization film can be obtained from the weight difference between the aluminum plates before and after dissolution of the anodization film. The anodization film of the aluminum plate is dissolved employing for example, an aqueous phosphoric acid chromic acid solution which is prepared by dissolving 35 ml of 85% by weight phosphoric acid and 20 g of chromium (IV) oxide in 1 liter of water. Micro pores are formed in the anodization film, and the density of the micro pores is preferably from 400 to 700/μm², and more preferably from 400 to 600/μm².

The aluminum plate, which has been subjected to anodizing treatment, is optionally subjected to sealing treatment. For the sealing treatment, it is possible to use known methods using hot water, boiling water, steam, a sodium silicate solution, an aqueous dichromate solution, a nitrite solution and an ammonium acetate solution. Further, well-known treatment with hydrophilic polymer aqueous solutions, such as polyvinyl phosphonic acid, polyacrylic acid, and polyacrylate, may also be performed

### <Material Used for a Photosensitive Layer>

### <Binder Resin>

In the present invention, the photosensitive layer contains, as a binder resin, a novolak resin containing a phenol component in an amount of 20% by weight or more and 100% by weight or less by weight ratio and a polyvinyl phenol polymer, and a content rate between the novolak resin and the polyvinyl phenol polymer (a weight of the novolak resin:a weight of the polyvinyl phenol polymer) is 7:3 to 3:7.

### (Novolak Resins)

Novolak resin is resin in which phenols are condensed with aldehyde, and the photosensitive layer contains a novolak resin containing a phenol component in an amount of 20% by weight or more and 100% by weight or less by weight ratio.

The term “containing a phenol component in an amount of 20% by weight or more and 100% by weight or less by weight ratio” means that in the resin formed by condensation, the ratio (% by weight) of the weight of the repeating unit formed by phenol to the weight of the entire resin is 20 or more and 100 or less.

Examples of the phenols used for novolak resins include phenol, m-cresol, p-cresol, a mixed cresol (mixture of m- and p-cresols), a mixture of phenol and cresol (m-cresol, p-cresol or a mixture of m- and p-cresols), pyrogallol, acrylamide having a phenolic hydroxyl group, methacrylamide having a phenolic hydroxyl group, acrylate having a phenolic hydroxyl group, methacrylate having a phenolic hydroxyl group, and hydroxyl styrene. Other examples of the phenols include substituted phenols such as iso-propylphenol, t-butylphenol, t-amylphenol, hexylphenol, cyclohexylphenol, 3-methyl-4-chloro-6-t-butylphenol, iso-propylcresol, t-butylcresol, and t-amylcresol. Preferred phenols are t-butylphenol and t-butylcresol.

On the other hand, examples of the aldehydes include aliphatic aldehydes such as formaldehyde, acetaldehyde, acrolein and crotonaldehyde; and aromatic aldehydes. Formaldehyde and acetaldehyde are preferred, and formaldehyde is especially preferred.

Among the above combination, preferable are phenol-formaldehyde resin, m-cresol-formaldehyde resin, p-cresol-formaldehyde resin, m-/p-cresol (mixed cresol)-formaldehyde resin, and phenol-cresol (m-cresol, p-cresol, o-cresol, m-/p-cresol (mixed), m-/o-cresol (mixed) or o-/p-cresol (mixed))-formaldehyde resin.

It is preferred that the novolak resin has a weight average molecular weight of not less than 1,000, and a number average molecular weight of not less than 200. It is more preferred that the novolak resin has a weight average molecular weight of from 1,500 to 300,000, a number average molecular weight of from 300 to 250,000, and a polydispersity (weight average molecular weight/number average molecular weight) of from 1.1 to 10. It is still more preferred that the novolak resin has a weight average molecular weight of from 2,000 to 10,000, a number average molecular weight of from 500 to 10,000, and a polydispersity (weight average molecular weight/number average molecular weight) of from 1.1 to 5. The molecular weight of the novolak resin is determined in terms of polystyrene employing monodisperse standard polystyrene according to GPC (gel permeation chromatography).

In the present invention, the photosensitive layer further contains polyvinyl phenol polymer as the binder. Examples of the polyvinyl phenol polymer include a homopolymer or copolymer of vinylphenol.

As the homopolymer of vinylphenol, the homopolymer of available p-vinylphenol, which is easy to obtain as a commercially available compound, can be used preferably. Examples of the copolymer include copolymers of p-vinylphenol and 2-hydroxy-ethyl acrylate, 2-hydroxy-ethyl methacrylate, styrene, methyl methacrylate, butyl acrylate, or hydroxyphenyl maleimide.

Among these compounds, it is the most desirable embodiment to use the homopolymer of vinylphenol from a viewpoint of compatibility with the above-mentioned novolak resin.

The homopolymer or copolymer of vinylphenol has, as a molecular weight, a weight average molecular weight of preferably 1500 to 50,000 and a number average molecular weight of preferably 1,000 to 10,000.

The weight ratio, i.e., ratio of content, of (novolak resin containing a phenol part in an amount of 20 weight % or more to 100 weigh % in weight ratio)/(homopolymer or copolymer of vinylphenol) is needed to be 7/3 to 3/7 from the view points of solvent resistance and printing resistance.

The total content of the novolak resin and polyvinyl phenol polymer is preferably 40% by weight to 90% by weight to the photosensitive layer, and more preferably 50% by weight to 80% by weight.

In the present invention, the photosensitive layer containing the specific novolak resin and polyvinyl phenol polymer as a binder, and the binder containing a cross linking agent with a specific ratio make it possible to obtain a planography plate material excellent in solvent resistance and printing resistance. The reasons for the above are not clear. However, it is presumed as follows.

After a printing plate is prepared, it is considered that the cross linking condition of the polymer in the photosensitive layer greatly influences solvent resistance and printing resistance of the photosensitive layer. In the photosensitive layer of the present invention, it is considered that the novolak resin containing phenol, which is excellent in compatibility, in a specific amount and polyvinyl phenol polymer exist in the state that the resin and the polymer become entwined with each other in complex arrangement. Further, the resin and the polymer in the above state are cross linked with a specific amount of the cross linking agent specified by the present invention, so that it is presumed that a particularly good three dimensional cross liked structure is formed in the photosensitive layer. The particularly excellent solvent resistance and printing resistance which the photosensitive layer with the structure of the present invention exhibits, may not be obtained by the single substance of a novolak resin or the single substance of a polyvinyl phenol polymer.

In addition to the above resin and the polymer, as the binder resin, it may be possible to add a well-known novolak resin not containing phenol and a well-known alkali-soluble resin in a range which the effect of the present invention is not spoiled.

### <Cross Linking Agent>

Examples of the cross linking agents used in the present invention, that is, examples of the cross linking agents which cross links with an alkali-soluble resin under the existence of an acid and reduces the solubility for an alkali, include: a resole resin, a phenol derivative described in the Japanese Unexamined Patent Publication No. 2000-35669 official report, a derivative of a methylol group or a methylol group, a melamine resin, a benzoguanamine resin, glycoluril resin, a furan resin, an isocyanate, a blocked isocyanate (isocyanate with a protective group) and the like. A melamine resin, or a cross linking agent with a methylol group or an acetylated methylol group may be preferable. Further, these cross linking agents may be used in combination of two or more. In the present invention, a melamine resin may be more preferable.

The melamine resin preferably used in the present invention is a resin with a structure that at least a part of a methylol group is alkoxilated in a mixture of methylolmelamine monomer, which is an initial condensation product of melamine and formaldehyde, and a low-order condensation product of melamine produced by the dehydration condensation of methylolmelamine and formaldehyde.

With regard to the content of the cross linking agent of the present invention, the weight ratio of a cross linking agent/a binder resin is needed by 0.25 or more and 0.50 or less from the viewpoints of solvent resistance and wear resistance.

### <Infrared Absorption Agent>

The infrared absorption agent used in the present invention has a light absorption region preferably in a range of 700 nm or more, and more preferably in an infrared range of 750 to 1200 nm, and exhibits light-heat conversion function for the light in the above wavelength range. Specifically, as the infrared absorption agent, various dyes and pigments which absorbs the light in the above range and generates heat may be employed.

### (Dyes)

As the dyes, well-known dyes, i.e., commercially available dyes or dyes described in literatures (for example, “Senryo Binran”, edited by Yuki Gosei Kagaku Kyokai, published in 1970) can be used. Examples thereof include azo dyes, metal complex azo dyes, pyrazoline azo dyes, anthraquinone dyes, phthalocyanine dyes, carbonium dyes, quinonimine dyes, methine dyes, and cyanine dyes. Among these dyes or pigments, dyes absorbing an infrared light or a near-infrared light are preferred in that a laser emitting an infrared light or a near-infrared light can be employed.

Examples of the dyes absorbing an infrared light or a near-infrared light include cyanine dyes disclosed in Japanese Patent O.P.I. Publication Nos. 58-125246, 59-84356, and 60-78787, methine dyes disclosed in Japanese Patent O.P.I. Publication Nos. 58-173696, 58-181690, and 58-194595, naphthoquinone dyes disclosed in Japanese Patent O.P.I. Publication Nos. 58-112793, 58-224793, 59-48187, 59-73996, 60-52940, and 60-63744, squarylium dyes disclosed in Japanese Patent O.P.I. Publication Nos. 58-112792, and cyanine dyes disclosed in British Patent No. 434,875. Further, near infrared absorbing sensitizing dyes described in U.S. Pat. No. 5,156,938 are suitably employed as the dyes. In addition, preferably employed are substituted arylbenzo(thio)pyrylium salts described in U.S. Pat. No. 3,881,924; trimethine-thiapyrylium salts described in Japanese Patent O.P.I. Publication No. 57-142645 (U.S. Pat. No. 4,327,169); pyrylium based compounds described in Japanese Patent O.P.I. Publication Nos. 58-181051, 58-220143, 59-41363, 59-84248, 59-84249, 59-146063, and 59-146061; cyanine dyes described in Japanese Patent O.P.I. Publication No. 59-216146; pentamethinethiopyrylium salts described in U.S. Pat. No. 4,283,475; pyrylium compounds described in Japanese Patent Publication No. 5-13514 and 5-19702, and Epolight III-178, Epolight III-130 or Epolight III-125.

Of these dyes, particularly preferred dyes are cyanine dyes, phthalocyanine dyes, oxonol dyes, squarylium dyes, pyrylium dyes, thiopyrylium dyes, and nickel thiolato complexes.

As the squarylium dyes, squarylium dyes described in U.S. Pat. No. 5,763,134 and squarylium dyes described in WO 2007/No. 083542 may be used preferably.

The content of infrared absorption agent dyes needed to obtain a proper sensitivity as a planography plate material is preferably 0.1 to 20 percent by weight to the total solid component of the photosensitive layer, more preferably 0.5 to 10 percent by weight, and still more preferably 1 to 5 percent by weight.

### (Pigment)

As pigment commercially available pigments and pigments described in Color Index (C.I.) Binran, “Saishin Ganryo Binran” (ed. by Nihon Ganryo Gijutsu Kyokai, 1977), “Saishin Ganryo Oyo Gijutsu” (CMC Publishing Co., Ltd., 1986), and “Insatsu Inki Gijutsu” (CMC Publishing Co., Ltd., 1984) can be used.

Kinds of the pigment include black pigment, yellow pigment, orange pigment, brown pigment, red pigment, violet pigment, blue pigment, green pigment, fluorescent pigment, metal powder pigment, and metal-containing colorants. Typical examples of the pigment include insoluble azo pigment, azo lake pigment, condensed azo pigment, chelate azo pigment, phthalocyanine pigment, anthraquinone pigment, perylene or perynone pigment, thioindigo pigment, quinacridone pigment, dioxazine pigment, isoindolinone pigment, quinophthalone pigment, lake pigment, azine pigment, nitroso pigment, nitro pigment, natural pigment, fluorescent pigment, inorganic pigment, and carbon black.

The particle size of the pigment is preferably 0.01 to 5 μm, more preferably 0.03 to 1 μm, still more preferably 0.05 to 0.5 μm.

The particle size of the pigment is preferably 0.01 μm or more in view of stability of dispersion in a coating solution, and preferably 5 μm or less in view of even coatability of the light-sensitive layer.

As a dispersion method of pigments, a conventional dispersion method used in manufacture of printing ink or toners can be used. Dispersion devices include an ultrasonic disperser, a sand mill, an atliter, a pearl mill, a super mill, a ball mill, an impeller, a disperser, a KD mill, a colloid mill, a dynatron, a three-roll mill, and a pressure kneader. The details are described in “Saishin Ganryo Oyou Gijutsu” (CMC Publishing Co., Ltd., 1986).

The content of infrared absorption agent pigments needed to obtain a proper sensitivity as a planography plate material is preferably 0.1 to 10 percent by weight to the total solid component of the photosensitive layer, and more preferably 0.5 to 5 percent by weight.

The above dyes and pigments may be used in combination of two or more kinds.

### (Acid Generating Agent)

Examples of the acid generating agent include onium salts such as a diazonium salt, an ammonium salt, a phosphonium salt, a sulfonium salt and an iodonium salt; and an organic halogen-containing compound. The diazonium salt or a trihaloalkyl-containing compound is preferred in obtaining high sensitivity. These acid generating compounds may be used as an admixture of two or more kinds thereof.

As the trihaloalkyl-containing compound, trihalomethyl-s-triazines, trihalomethyl-oxadiazoles or tribromomethylsulfonyl compounds disclosed in U.S. Pat. No. 4,239,850 are preferred.

The acid generation compound is an organic halogen-containing compound in view of sensitivity to infrared rays and storage stability of an image forming material using it. The organic halogen-containing compound is preferably a halogenated alkyl-containing triazines or a halogenated alkyl-containing oxadiazoles. Of these, halogenated alkyl-containing s-triazines are especially preferable.

Examples of the halogenated alkyl-containing oxadiazoles include 2-halomethyl-1,3,4-oxadiazole compounds disclosed in Japanese Patent O.P.I. Publication Nos. 54-74728, 55-24113, 55-77742, 60-3626 and 60-138539. Preferable examples of the 2-halomethyl-1,3,4-oxadiazole compounds are listed below.

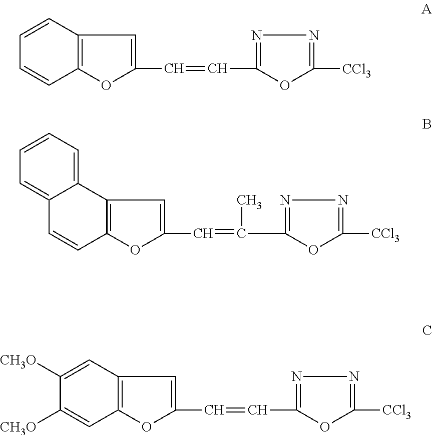

The halogenated alkyl containing triazine compound is preferably a compound represented by the following formula TZN:

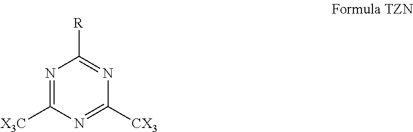

In Formula TZN, R represents an alkyl group, a halogenated alkyl, an alkoxy group, a substituted or unsubstituted styryl group, or a substituted or unsubstituted aryl group (for example, phenyl or naphthyl); and X represents a halogen atom.

Examples of the triazine compound represented by formula TZN will be listed below.

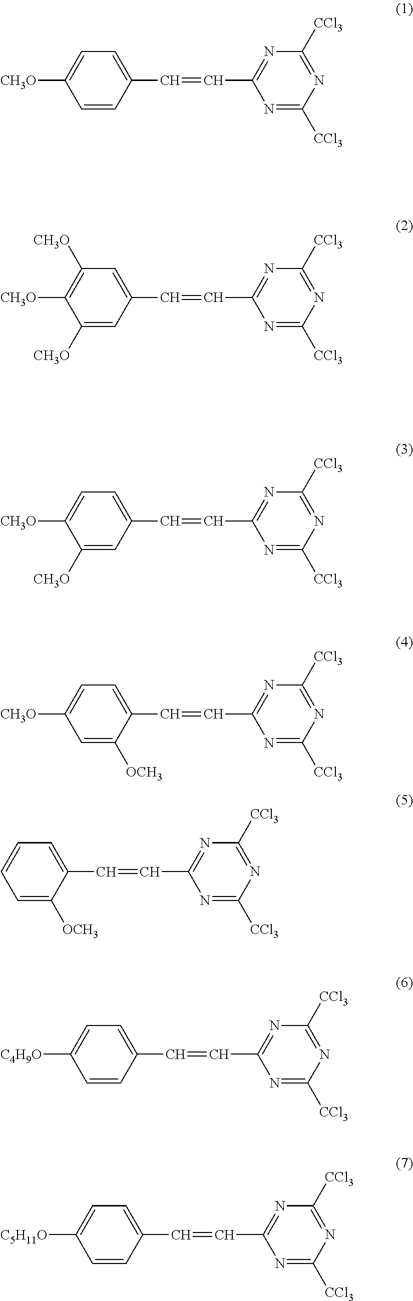

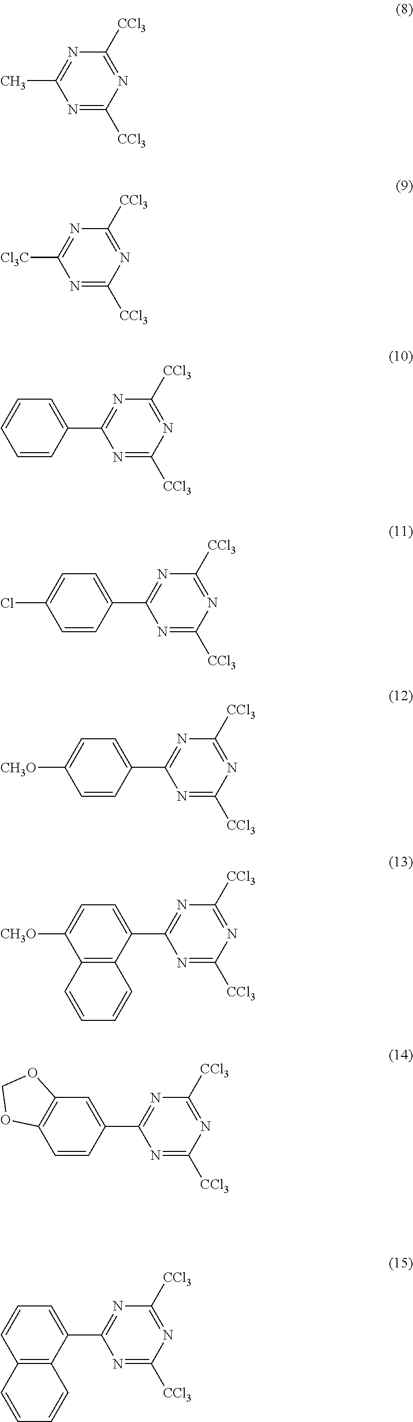

As the acid generating compound used in the present invention, a triazine compound is particularly desirable from the viewpoints of sensibility, solvent resistance, and wear resistance.

The content of the acid generating compound is desirably in a range of 1 to 30 percent by weight to the total solid component of the photosensitive layer, and more desirably in a range of 3 to 10 percent by weight. If the content of the acid generating compound is 1 percent by weight or more, it is preferable from the viewpoints of sensibility, solvent resistance, and wear resistance for the acid generation needed to the cross linking between the binder resin and the cross linking agent. If the content of the acid generating compound is 30 percent by weight or less, it is preferable from the viewpoints of solvent resistance and wear resistance with relative ratio of the binder resin and the cross linking agent

### <Other Components>

### <Visualizing Agent>

As the visualizing agent, other dyes can be employed besides the salt-forming organic dyes as described above. Preferred dyes including the salt-forming organic dyes are oil-soluble dyes and basic dyes. Those changing the color by the action of a free radical or an acid are preferably used. The term “changing the color” means changing from colorless to color, from color to colorless, or from the color to different color. Preferred dyes are those changing the color by forming salts with an acid.

Examples of the dyes changing from color to colorless or from the color to different color include triphenyl methane, diphenyl methane, oxazine, xanthene, iminonaphthoquinone, azomethine or anthraquinone dyes represented by Victoria pure blue BOH (product of Hodogaya Kagaku), Oil blue #603 (product of Orient Kagaku kogyo), Patent pure blue (product of Sumitomo Mikuni Kagaku Co., Ltd.), Crystal violet, Brilliant green, Ethyl violet, Methyl violet, Methyl green, Erythrosine B, Basic fuchsin, Marachite green, Oil red, m-cresol purple, Rhodamine B, Auramine, 4-p-diethylaminophenyliminonaphthoquinone or cyano-p-diethylaminophenylacetoanilide.

Examples of the dyes changing from colorless to color include leuco dyes and primary or secondary amines represented by triphenylamine, diphenylamine, o-chloroaniline, 1,2,3-triphenylguanidine, diaminodiphenylmethane, p,p′-bis-dimethylaminodiphenylamine, 1,2-dianilinoethylene, p,p′,p″-tris-dimethylaminotriphenylmethane, p,p′-bis-dimethylaminodiphenylmethylimine, p,p′,p″-triamino-o-methyltriphenylmethane, p,p′-bis-dimethylaminodiphenyl-4-anilinonaphthylmethane, and p,p′,p″-triaminotriphenylmethane. These dyes may be used alone or as an admixture of two or more kinds thereof. Especially preferred dyes are Victoria pure blue BOH (product of Hodogaya Kagaku) and Oil blue #603.

These visualizing agents may be added with a ratio of preferably 0.01 to 10 percent by weight to the total solid component of the photosensitive layer, and more preferably 0.1 to 3 percent by weight.

### <Colorant>

As a colorant, well-known colorants including commercially available one may be used conveniently. Examples of the colorant include colorants described in the revised new edition of “pigment handbook” edited by Japan pigment technical societies (Seibundo Shinkosha), Color Index handbook, and the like.

The kinds of pigments include a black pigment, an yellow pigment, a red pigment, a brown pigment, a purple pigment, a blue pigment, a green pigment, a fluorescent pigment, a metallic flake pigment, and the like. Specific examples of the pigments include inorganic pigments (titanium dioxide, carbon black, graphite, Zinc oxide, Prussian blue, cadmium sulfide, iron oxide, and a chromate salt of lead, zinc, barium, and calcium); and organic pigments (pigments of an azo type, a thioindigo type, an anthraquinone type, an anthraanthrone type, and a triphen dioxazin type, a vat dye pigment, a phthalocyanine pigment and its derivative, a quinacridone pigment, and the like).

Moreover, a cyanine dye which substantially does not have absorption in an infrared region my also be preferably used as a colorant

### <Surfactant)>

In the present invention, the light-sensitive layer can contain surfactants. Further, in the case of the light-sensitive layer having a two light-sensitive layer structure, at least one of the upper layer and the lower layer can contain non-ionic surfactants as disclosed in Japanese Patent O.P.I. Publication Nos. 62-251740 and 3-208514, amphoteric surfactants as disclosed in Japanese Patent O.P.I. Publication Nos. 59-121044 and 4-13149, siloxane compounds disclosed in EP 950517, or fluorine-containing copolymers disclosed in Japanese Patent O.P.I. Publication Nos. 62-170950, 11-288093, and 2003-57820, in order to improve the coatability and increase stability under various developing conditions.

Examples of the non-ionic surfactants include sorbitan tristearate, sorbitan monopalmitate, sorbitan trioleate, stearic acid monoglyceride, polyoxyethylene sorbitan monooleate, and polyoxyethylene nonylphenyl ether. Examples of the amphoteric surfactants include alkyldi(aminoethyl)-glycine, alkylpoly(aminoethyl)glycine hydrochloride, 2-alkyl-N-carboxyethyl-N-hydroxyethylimidazolinium betaine, and N-tetradecyl-N,N-betaine type compounds (for example, trade name: AMOGEN K produced by DAIICHI KOGYO CO., LTD.).

Examples of the siloxane compounds include a block copolymer of dimethyl polysiloxane and polyalkylene oxide, for example, polyalkylene oxide-modified silicons such as DBE-224, DBE-621, DBE-712, DBE-732, and DBE-534, each produced by Chisso Co., Ltd., and Tego Glide 100 produced by Tego Co., Ltd.

The surfactant preferably has a content of 0.01-15% by weight, based on the total solid content of photosensitive layer, more preferably has a content of 0.1-5% by weight, and still more preferably has a content of 0.05-0.5% by weight.

### <Coating, Drying>

Solvents used for preparing a light sensitive layer coating liquid include alcohols such as methanol, ethanol, propanol, isopropanol, sec-butanol, isobutanol, hexanol, benzyl alcohol, diethylene glycol, triethylene glycol, tetraethylene glycol and 1,5-pentane diol; ethers such as propylene glycol monomethyl ether, propylene glycol monoethyl ether acetate, propylene glycol monoethyl ether, propylene glycol monobutyl ether, dipropylene glycol monomethyl ether and tripropylene glycol monomethyl ether; ketones such as acetone, methyl ethyl ketone, methyl isobutyl ketone, diacetone alcohol, cyclopentanone, dioxolane, cyclohexanone, methyl cyclohexanone and γ-butyrolactone; and esters such as ethyl lactate, butyl lactate, diethyl oxalate, methyl benzoate and ethyl acetate.

The light sensitive layer coating liquid is coated on the support according to a conventional coating method, and dried to obtain a light sensitive planographic printing plate material. The coating methods include an air doctor coating method, a blade coating method, a wire bar coating method, a knife coating method, a dip coating method, a reverse roll coating method, a gravure coating method, a cast coating method, a curtain coating method and an extrusion coating method.

The coated light sensitive layer is dried at a temperature of preferably at 60 to 160° C., more preferably 80 to 140° C. and still more preferably 90 to 120° C.

The dry coated weight of the photosensitive layer is preferably 0.5 to 4 g/m², more preferably 1.0 to 2.5 g/m², still more preferably 1.2 to 2.0 g/m² from the viewpoints of sensitivity, printing resistance, and cost. If the dry coated weight is 0.5 g/m² or more, it is preferable from the viewpoint of printing resistance. If the dry coated weight is 4 g/m² or less, it is preferable from the viewpoint of sensitivity as well as the cost of the photosensitive layer.

Further, the preferable embodiment is that a dried coated weight (g/m²) of the photosensitive layer of the planography plate material of the present invention satisfies Formula (1) for a surface roughness Ra (μm) of the surface of a support.

Dried coated weight of a photosensitive layer−Ra≧1.0 Formula (1)

The satisfaction of Formula (1) makes it possible to allow a photosensitive layer uniformly to cover convexo-concave portions of the support. Further, image potions at the time of image formation have a proper protrusion amount from the surface of the support (flat surface supposed to be in contact with average convex portions in the convexo-concave portions. In the case where the image potions have a proper protrusion amount, the protrusion amount is deemed as a wear margin amount until the surface of the support at the image portions expose. With this, the wear resistance of the image portions becomes good.

### <Image Exposure, Heat Treatment, Development>

The planography plate material of the present invention is subjected to image exposure so as to form latent images, then to heat treatment with which regions on which the latent images are formed are cross linked so as to form images, and further to development treatment with which photosensitive layers of non-exposed portions are removed, and furthermore to gum treatment if needed, whereby a planography plate is formed.

Imagewise exposure is carried out employing a light source emitting light with an emission wavelength of not shorter than 700 nm. The light sources for the imagewise exposure include, for example, a semiconductor laser, a He—Ne laser, a YAG laser, and carbon dioxide gas laser. The output power of the light sources is ordinarily not less than 50 mW, and preferably not less than 100 mW.

A laser scanning method by means of a laser beam includes a method of scanning on an outer surface of a cylinder, a method of scanning on an inner surface of a cylinder and a method of scanning on a plane. In the method of scanning on an outer surface of a cylinder, laser beam exposure is conducted while a drum around which a recording material is wound is rotated, in which main scanning is represented by the rotation of the drum, while sub-scanning is represented by the movement of the laser beam. In the method of scanning on an inner surface of a cylinder, a recording material is fixed on the inner surface of a drum, a laser beam is emitted from the inside, and main scanning is carried out in the circumferential direction by rotating a part of or an entire part of an optical system, while sub-scanning is carried out in the axial direction by moving straight a part of or an entire part of the optical system in parallel with a shaft of the drum. In the method of scanning on a plane, main scanning by means of a laser beam is carried out through a combination of a polygon mirror, a galvano mirror and an fθ lens, and sub-scanning is carried out by moving a recording medium. The method of scanning on an outer surface of a cylinder, and the method of scanning on an inner surface of a cylinder are preferred in optical system accuracy and high density recording.

After image exposure, the planography plate material is subjected to heat treatment immediately after the image exposure or after a suitable period of time has elapsed. The heat treatment is conducted usually by use of an apparatus to convey a planography plate material at a constant speed in a heating furnace capable of being set at a predetermined temperature. The heating processing condition is adjustable such that temperature setting in the furnace and conveyance speed setting, i.e., detention time setting in the furnace are appropriately adjusted.

The setting of the temperature range which the plate surface of the planography plate material reaches in the heat treatment is more important than the setting of the temperature in the furnace. When the planography plate material of the present invention is treated by the heat treating condition that the plate-surface reaching temperature of the planography plate material is made preferably 130° C. or more and less than 155° C., it is possible to provide very good solvent resistance and wear resistance without causing poor development due to excessive heating.

In the heat treatment, in addition to an apparatus including one heating zone in a heating furnace, an apparatus including a plurality of zones each independently adjustable in terms of heating temperature in a heating furnace may be preferably employed. In the temperature setting for the plurality of zones, the temperature of a zone through which a planography plate material passes lastly is preferably set to the lowest, and in addition, a preferable embodiment is that the temperature for a zone through which a planography plate material passes first is set to the highest. In such an embodiment, time until the temperature of a planography plate material reaches from a room temperature to a proper temperature can be shortened, so that the total time for heat treatment can be shortened. In other words, it becomes possible to improve the productivity of the plate production.

The temperature set for a zone through which a planography plate material passes lastly is preferably 5° C. or more lower than the highest temperature set the previous zones, and more preferably 10° C. or more lower.

The technique to lower the temperature set for a zone through which a planography plate material passes lastly provides a merit in terms of suppression of deformation (so-called “ripple”) due to thermal history of the planography plate material from the heat treatment to a development treatment.

After the heat treatment, the planography plate material is subjected to development treatment immediately after the heat treatment or after a proper period of time has elapsed after the heat treatment. For the development treatment, usually an automatic development device is used.

### <Developer>

The planographic printing plate material of the invention is developed with a developer to obtain a planographic printing plate. The developer is preferably an aqueous alkaline developer. As the aqueous alkaline developer, there is, for example, an aqueous solution containing an alkali metal salt such as sodium hydroxide, potassium hydroxide, sodium carbonate, potassium carbonate, sodium metasilicate, potassium metasilicate or di or trisodium phosphate. The metal salt concentration of the developer is preferably 0.05 to 20% by weight, and more preferably 0.1 to 10% by weight. The developer optionally contains an anionic surfactant, an amphoteric surfactant or an organic solvent such as alcohol. The organic solvent includes propylene glycol, ethylene glycol monophenyl ether, benzyl alcohol and n-propyl alcohol.

The developer temperature is preferably from 15 to 40° C., and preferably from 25 to 35° C. The developing time is preferably from 1 second to 2 minutes, and more preferably from 10 to 45 seconds.

If necessary, the light sensitive layer surface can be rubbed with a brush or a molleton during development. The developed surface of the developed planographic printing plate material is washed with water and/or desensitized with an aqueous desensitizing solution.

Examples of the aqueous desensitizing solution include an aqueous solution of natural water-soluble polymers such as gum arabic, dextrin and carboxymethylcellulose or synthetic water-soluble polymers such as polyvinyl alcohol, polyvinyl pyrrolidone, and polyacrylic acid.

The aqueous desensitizing solution may optionally contain an acid or a surface-active agent. The desensitized planographic printing plate is dried and applied for printing.

### Example

The present invention will be explained in detail below employing examples, but is not limited thereto. In the examples, “parts” is “parts by weight”, unless otherwise specified.

### Example 1

### Production of Support

A 0.30 mm thick aluminum plate (material 1050, refining H16) was immersed in an aqueous 1% by weight sodium hydroxide solution at 50° C. to cause an aluminum dissolution amount of 2 g/m², washed with water, immersed in an aqueous 1% by weight hydrochloric acid solution at 25° C. for 30 seconds to neutralize, and then washed with water.

Subsequently, the aluminum plate was subjected to electrolytic surface-roughening treatment in an electrolytic solution containing 10 g/liter of hydrochloric acid, 10 g/liter of acetic acid, and 8 g/liter of aluminum by use of an alternating current with a sine waveform on the condition that a peak electric current density and a quantity of electricity at the time of an anode were made as sown in Table 1. At this time, the distance between the sample surface and the electrode was made 10 mm.

After the electrolytic surface-roughening treatment, the resulting aluminum plate was immersed in an aqueous 10% by weight phosphoric acid solution at 50° C. and etched to cause an aluminum dissolution amount (including smut caused on the roughened surface) of 0.7 g/m², and washed with water. Successively, the aluminum plate was immersed in an aqueous 10% sulfuric acid solution kept at 25° C. for 10 seconds to neutralize, and then washed with water. Subsequently, the aluminum plate was subjected to anodizing treatment in an aqueous 20% by weight sulfuric acid solution at 25° C. with a constant current condition of 10 A/dm² so as to cause an anodizing layered amount of 3.0 g/m², washed with water, and dried, whereby Supports 1 to 5 were produced.

The surface roughness Ra of the roughened surface of the resulting support was measured by a sensing pin with a tip diameter of 2 μm. The measurement results are shown in Table 1.

TABLE 1

| | | Quantity of | |
|---|---|---|---|
| | Electric current density | electricity at the time | |
| Support No. | peak value (A/dm²) | of an anode (C/dm²) | Ra (μm) |
| Support 1 | 75 | 375 | 0.35 |
| Support 2 | 80 | 400 | 0.4 |
| Support 3 | 90 | 450 | 0.5 |
| Support 4 | 100 | 500 | 0.6 |
| Support 5 | 105 | 525 | 0.65 |

### <Production of Photosensitive Layer Coating Liquids 6 to 44>

Each of materials with solid component ratio sown in Tables 2 to 7 are dissolved in a mixture solvent of MEK (methyl ethyl ketone)/PGM (propylene glycol monomethyl ether)=20/80 so as to make a solid component of a coating liquid to be 8% by weight, sufficiently mixed, and then filtered, whereby respective Photosensitive layer coating liquids were produced.

TABLE 2

| | Coating liquid 6 | | Coating liquid 7 | | Coating liquid 8 | | Coating liquid 9 | | Coating liquid 10 | | Coating liquid 11 | | Coating liquid 12 | |
|---|---|---|---|---|---|---|---|---|---|---|---|---|---|---|
| | Material | | Material | | Material | | Material | | Material | | Material | | Material | |
| | No. | *1 | No. | *1 | No. | *1 | No. | *1 | No. | *1 | No. | *1 | No. | *1 |
| Binder A: | 1 | 26.00 | 3 | 44.10 | 4 | 30.00 | 5 | 81.00 | | | 6 | 35.00 | 6 | 52.00 |
| Novolak | | | | | | | | | | | | | | |
| Binder B: | 1 | 39.00 | 3 | 25.00 | 1 | 35.10 | | | 1 | 63.00 | | | | |
| other | | | | | | | | | | | | | | |
| than A | | | | | | | | | | | | | | |
| Cross | 1 | 24.10 | 2 | 20.00 | 1 | 28.00 | 1 | 8.10 | 1 | 29.00 | 3 | 35.00 | 3 | 40.00 |
| linking | | | | | | | | | | | | | | |
| agent | | | | | | | | | | | | | | |
| Infrared | 4 | 2.50 | 2 | 1.75 | 1 | 2.00 | 4 | 1.45 | 1 | 1.45 | 1 | 5.00 | 1 | 3.00 |
| absorbing | | | | | | | | | | | | | | |
| agent | | | | | | | | | | | | | | |
| Acid | 1 | 7.00 | 3 | 8.00 | 6 | 3.50 | 1 | 8.00 | 1 | 5.00 | 4 | 23.00 | 6 | 3.00 |
| generating | | | | | | | | | | | | | | |
| agent | | | | | | | | | | | | | | |
| Colorant | 3 | 1.25 | 2 | 1.00 | 1 | 1.30 | 3 | 1.30 | 1 | 1.40 | 2 | 1.85 | 3 | 1.85 |
| Surfactant | 2 | 0.15 | 1 | 0.15 | 2 | 0.10 | 1 | 0.15 | 1 | 0.15 | 2 | 0.15 | 1 | 0.15 |

| | | | | | | | |
|---|---|---|---|---|---|---|---|
| Ratio of | 0.37 | 0.29 | 0.43 | 0.10 | 0.46 | 1.00 | 0.77 |
| cross | | | | | | | |
| linking | | | | | | | |
| agent/ | | | | | | | |
| binder | | | | | | | |
| (b/a) | | | | | | | |
| A:B | 4:6 | 6.4:3.6 | 4.6:5.4 | 10:0 | 0:10 | 10:0 | 10:0 |
| Remarks | Inventive | Inventive | Inventive | Comparative | Comparative | Comparative | Comparative |

*1: Solid component ratio (weight %)

TABLE 3

| | Coating liquid 13 | | Coating liquid 14 | | Coating liquid 15 | | Coating liquid 16 | | Coating liquid 17 | | Coating liquid 18 | | Coating liquid 19 | |
|---|---|---|---|---|---|---|---|---|---|---|---|---|---|---|
| | Material | | Material | | Material | | Material | | Material | | Material | | Material | |
| | No. | *1 | No. | *1 | No. | *1 | No. | *1 | No. | *1 | No. | *1 | No. | *1 |
| Binder A: | 5 | 64.00 | | | 7 | 64.50 | 8 | 72.50 | 5 | 49.00 | 7 | 39.00 | 6 | 48.50 |
| Novolak | | | | | | | | | | | | | | |
| Binder B: | | | 1 | 64.00 | | | | | 4 | 20.00 | 5 | 25.00 | 6 | 21.00 |
| other | | | | | | | | | | | | | | |
| than A | | | | | | | | | | | | | | |
| Cross | 5 | 22.00 | 4 | 22.00 | 2 | 24.00 | 1 | 19.00 | 2 | 20.00 | 1 | 25.00 | 2 | 18.00 |
| linking | | | | | | | | | | | | | | |
| agent | | | | | | | | | | | | | | |
| Infrared | 1 | 4.50 | 1 | 4.50 | 2 | 2.00 | 1 | 1.85 | 1 | 2.00 | 3 | 2.00 | 1 | 2.50 |
| absorbing | | | | | | | | | | | | | | |
| agent | | | | | | | | | | | | | | |
| Acid | 1 | 8.50 | 5 | 8.50 | 2 | 8.00 | 3 | 5.00 | 4 | 7.85 | 1 | 8.00 | 4 | 9.00 |
| generating | | | | | | | | | | | | | | |
| agent | | | | | | | | | | | | | | |
| Colorant | 1 | 0.85 | 2 | 0.85 | 3 | 1.35 | 3 | 1.50 | 1 | 1.00 | 3 | 0.90 | 1 | 0.85 |
| Surfactant | 1 | 0.15 | 2 | 0.15 | 1 | 0.15 | 2 | 0.15 | 1 | 0.15 | 2 | 0.10 | 1 | 0.15 |

| | | | | | | | |
|---|---|---|---|---|---|---|---|
| Ratio of | 0.34 | 0.34 | 0.37 | 0.26 | 0.29 | 0.39 | 0.26 |
| cross | | | | | | | |
| linking | | | | | | | |
| agent/ | | | | | | | |
| binder | | | | | | | |
| (b/a) | | | | | | | |

| | | | | | | | |
|---|---|---|---|---|---|---|---|
| A:B | 10:0 | 0:10 | 10:0 | 10:0 | 7:3 | 6:4 | 7:3 |
| Remarks | Comparative | Comparative | Comparative | Comparative | Comparative | Comparative | Comparative |

*1: Solid component ratio (weight %)

TABLE 4

| | Coating liquid 20 | | Coating liquid 21 | | Coating liquid 22 | | Coating liquid 23 | | Coating liquid 24 | | Coating liquid 25 | | Coating liquid 26 | |
|---|---|---|---|---|---|---|---|---|---|---|---|---|---|---|
| | Material | | Material | | Material | | Material | | Material | | Material | | Material | |
| | No. | *1 | No. | *1 | No. | *1 | No. | *1 | No. | *1 | No. | *1 | No. | *1 |
| Binder A: | 7 | 26.00 | 1 | 57.00 | 1 | 6.50 | 1 | 13.00 | 1 | 19.50 | 1 | 32.50 | 1 | 45.50 |
| Novolak | | | | | | | | | | | | | | |
| Binder B: | 1 | 39.00 | | | 1 | 58.50 | 1 | 52.00 | 1 | 45.50 | 1 | 32.50 | 1 | 19.50 |
| other | | | | | | | | | | | | | | |
| than A | | | | | | | | | | | | | | |
| Cross | 1 | 24.10 | 1 | 32.10 | 1 | 24.10 | 1 | 24.10 | 1 | 24.10 | 1 | 24.10 | 1 | 24.10 |
| linking | | | | | | | | | | | | | | |
| agent | | | | | | | | | | | | | | |
| Infrared | 4 | 2.50 | 4 | 2.50 | 4 | 2.50 | 4 | 2.50 | 4 | 2.50 | 4 | 2.50 | 4 | 2.50 |
| absorbing | | | | | | | | | | | | | | |
| agent | | | | | | | | | | | | | | |
| Acid | 1 | 7.00 | 1 | 7.00 | 1 | 7.00 | 1 | 7.00 | 1 | 7.00 | 1 | 7.00 | 1 | 7.00 |
| generating | | | | | | | | | | | | | | |
| agent | | | | | | | | | | | | | | |
| Colorant | 3 | 1.25 | 3 | 1.25 | 3 | 1.25 | 3 | 1.25 | 3 | 1.25 | 3 | 1.25 | 3 | 1.25 |
| Surfactant | 2 | 0.15 | 2 | 0.15 | 2 | 0.15 | 2 | 0.15 | 2 | 0.15 | 2 | 0.15 | 2 | 0.15 |

| | | | | | | | |
|---|---|---|---|---|---|---|---|
| Ratio of | 0.37 | 0.56 | 0.37 | 0.37 | 0.37 | 0.37 | 0.37 |
| cross | | | | | | | |
| linking | | | | | | | |
| agent/ | | | | | | | |
| binder | | | | | | | |
| (b/a) | | | | | | | |
| A:B | 4:6 | 10:0 | 1:9 | 2:8 | 3:7 | 5:5 | 7:3 |
| Remarks | Comparative | Comparative | Comparative | Comparative | Inventive | Inventive | Inventive |

*1: Solid component ratio (weight %)

TABLE 5

| | Coating liquid 27 | | Coating liquid 28 | | Coating liquid 29 | | Coating liquid 30 | | Coating liquid 31 | | Coating liquid 32 | | Coating liquid 33 | |
|---|---|---|---|---|---|---|---|---|---|---|---|---|---|---|
| | Material | | Material | | Material | | Material | | Material | | Material | | Material | |
| | No. | *1 | No. | *1 | No. | *1 | No. | *1 | No. | *1 | No. | *1 | No. | *1 |
| Binder A: | 1 | 52.00 | 1 | 58.50 | 1 | 21.15 | 1 | 22.35 | 1 | 49.35 | 1 | 52.15 | 1 | 18.09 |
| Novolak | | | | | | | | | | | | | | |
| Binder B: | 1 | 13.00 | 1 | 6.50 | 1 | 49.35 | 1 | 52.15 | 1 | 21.15 | 1 | 22.35 | 1 | 42.21 |
| other | | | | | | | | | | | | | | |
| than A | | | | | | | | | | | | | | |
| Cross | 1 | 24.10 | 1 | 24.10 | 1 | 18.60 | 1 | 14.60 | 1 | 18.60 | 1 | 14.60 | 1 | 28.80 |
| linking | | | | | | | | | | | | | | |
| agent | | | | | | | | | | | | | | |
| Infrared | 4 | 2.50 | 4 | 2.50 | 4 | 2.50 | 4 | 2.50 | 4 | 2.50 | 4 | 2.50 | 4 | 2.50 |
| absorbing | | | | | | | | | | | | | | |
| agent | | | | | | | | | | | | | | |
| Acid | 1 | 7.00 | 1 | 7.00 | 1 | 7.00 | 1 | 7.00 | 1 | 7.00 | 1 | 7.00 | 1 | 7.00 |
| generating | | | | | | | | | | | | | | |
| agent | | | | | | | | | | | | | | |
| Colorant | 3 | 1.25 | 3 | 1.25 | 3 | 1.25 | 3 | 1.25 | 3 | 1.25 | 3 | 1.25 | 3 | 1.25 |
| Surfactant | 2 | 0.15 | 2 | 0.15 | 2 | 0.15 | 2 | 0.15 | 2 | 0.15 | 2 | 0.15 | 2 | 0.15 |

| | | | | | | | |
|---|---|---|---|---|---|---|---|
| Ratio of | 0.37 | 0.37 | 0.26 | 0.20 | 0.26 | 0.20 | 0.48 |
| cross | | | | | | | |
| linking | | | | | | | |
| agent/ | | | | | | | |
| binder | | | | | | | |
| (b/a) | | | | | | | |
| A:B | 8:2 | 9:1 | 3:7 | 3:7 | 7:3 | 7:3 | 3:7 |
| Remarks | Comparative | Comparative | Inventive | Comparative | Inventive | Comparative | Inventive |

*1: Solid component ratio (weight %)

TABLE 6

| | Coating liquid 34 | | Coating liquid 35 | | Coating liquid 36 | | Coating liquid 37 | | Coating liquid 38 | | Coating liquid 39 | | Coating liquid 40 | |
|---|---|---|---|---|---|---|---|---|---|---|---|---|---|---|
| | Material | | Material | | Material | | Material | | Material | | Material | | Material | |
| | No. | *1 | No. | *1 | No. | *1 | No. | *1 | No. | *1 | No. | *1 | No. | *1 |
| Binder A: | 1 | 16.83 | 1 | 42.21 | 1 | 39.27 | 1 | 14.10 | 1 | 56.40 | 1 | 12.06 | 1 | 48.24 |
| Novolak | | | | | | | | | | | | | | |
| Binder B: | 1 | 39.27 | 1 | 18.09 | 1 | 16.83 | 1 | 56.40 | 1 | 14.10 | 1 | 48.24 | 1 | 12.06 |
| other | | | | | | | | | | | | | | |
| than A | | | | | | | | | | | | | | |
| Cross | 1 | 33.00 | 1 | 28.80 | 1 | 33.00 | 1 | 18.60 | 1 | 18.60 | 1 | 28.80 | 1 | 28.80 |
| linking | | | | | | | | | | | | | | |
| agent | | | | | | | | | | | | | | |
| Infrared | 4 | 2.50 | 4 | 2.50 | 4 | 2.50 | 4 | 2.50 | 4 | 2.50 | 4 | 2.50 | 4 | 2.50 |
| absorbing | | | | | | | | | | | | | | |
| agent | | | | | | | | | | | | | | |
| Acid | 1 | 7.00 | 1 | 7.00 | 1 | 7.00 | 1 | 7.00 | 1 | 7.00 | 1 | 7.00 | 1 | 7.00 |
| generating | | | | | | | | | | | | | | |
| agent | | | | | | | | | | | | | | |
| Colorant | 3 | 1.25 | 3 | 1.25 | 3 | 1.25 | 3 | 1.25 | 3 | 1.25 | 3 | 1.25 | 3 | 1.25 |
| Surfactant | 2 | 0.15 | 2 | 0.15 | 2 | 0.15 | 2 | 0.15 | 2 | 0.15 | 2 | 0.15 | 2 | 0.15 |

| | | | | | | | |
|---|---|---|---|---|---|---|---|
| Ratio of | 0.59 | 0.48 | 0.59 | 0.26 | 0.26 | 0.48 | 0.48 |
| cross | | | | | | | |
| linking | | | | | | | |
| agent/ | | | | | | | |
| binder | | | | | | | |
| (b/a) | | | | | | | |
| A:B | 3:7 | 7:3 | 7:3 | 2:8 | 8:2 | 2:8 | 8:2 |
| Remarks | Comparative | Inventive | Comparative | Comparative | Comparative | Comparative | Comparative |

*1: Solid component ratio (weight %)

TABLE 7

| | Coating liquid 41 | | Coating liquid 42 | | Coating liquid 43 | | Coating liquid 44 | |
|---|---|---|---|---|---|---|---|---|
| | | Solid | | Solid | | Solid | | Solid |
| | | component | | component | | component | | component |
| | Material | ratio | Material | ratio | Material | ratio | Material | ratio |
| | No. | (weight %) | No. | (weight %) | No. | (weight %) | No. | (weight %) |
| Binder A: | 1 | 37.25 | 1 | 28.05 | 1 | 0.00 | 1 | 65.00 |
| Novolak | | | | | | | | |
| Binder B: | 1 | 37.25 | 1 | 28.05 | 1 | 65.00 | 1 | 0.00 |
| other | | | | | | | | |
| than A | | | | | | | | |
| Cross | 1 | 14.60 | 1 | 33.00 | 1 | 24.10 | 1 | 24.10 |
| linking | | | | | | | | |
| agent | | | | | | | | |
| Infrared | 4 | 2.50 | 4 | 2.50 | 4 | 2.50 | 4 | 2.50 |
| absorbing | | | | | | | | |
| agent | | | | | | | | |
| Acid | 1 | 7.00 | 1 | 7.00 | 1 | 7.00 | 1 | 7.00 |
| generating | | | | | | | | |
| agent | | | | | | | | |
| Colorant | 3 | 1.25 | 3 | 1.25 | 3 | 1.25 | 3 | 1.25 |
| Surfactant | 2 | 0.15 | 2 | 0.15 | 2 | 0.15 | 2 | 0.15 |

| | | | | |
|---|---|---|---|---|
| Ratio of | 0.20 | 0.59 | 0.37 | 0.37 |
| cross | | | | |
| linking | | | | |
| agent/ | | | | |
| binder | | | | |
| (b/a) | | | | |
| A:B | 5:5 | 5:5 | 0:10 | 10:0 |
| Remarks | Comparative | Comparative | Comparative | Comparative |

Respective materials shown in Table 2 to Table 7 are as follows.

### <Binder A: Novolak>

1. phenol/m-cresol/p-cresol=50/20/20, Mw: 18000
2. phenol/m-cresol/p-cresol=50/20/20, Mw: 6000
3. phenol/m-cresol/p-cresol=25/45/30, Mw: 10000
4, phenol=100, Mw: 1000
5. m-cresol/p-cresol=60/40, Mw: 6000
6. m-cresol=100, Mw: 13000
7. xylenol/m-cresol/p-cresol=20/45/35, Mw: 37000
8. phenol/m-cresol/p-cresol=5/57/38, Mw: 10000
<Binder B: Other than A>
1. homopolymer of p-vinylphenol, Mw: 10000
2. homopolymer of p-vinylphenol, Mw: 5000
3. p-vinylphenol/HEMA=50/50, Mw: 10000

### 4. HyPMA/AN/MMA=40/30/30, Mw: 22000

### 5. HyPMI/AN/MMA=26/37/37, Mw: 14000

### 6. HyPMA/MAN/MMA/BzMA=34/20/36/10, Mw: 26000

HEMA: 2 hydroxy ethyl acrylate

HyPMA: Hydroxyphenyl methacrylamide

AN: Acrylonitrile

MMA: Methyl methacrylate

HyPMI: Hydroxyphenyl maleimide

MAN: Methacrylonitrile

BzMA: Benzyl methacrylate

### <Cross Linking Agent>

1. Methylated Melamine Resin: Cymel303 (produced by Japanese Psytec Industries, Monomer: about 60%)
2. Methylated Melamine Resin: Nikalack MW-390 (produced by Sanwa Chemical, Monomer: 96% or more)
3. Resole Resin: BKS-5928 (produced by Union Carbide Corp.)
4. 2,6-Dihydroxymethyl-4-methylphenol

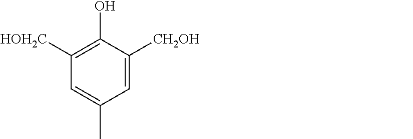

5. 2,2-bis(4-hydroxy-3,5-dihydroxymethylphenyl)propane

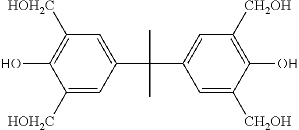

### <Infrared Absorption Agent>

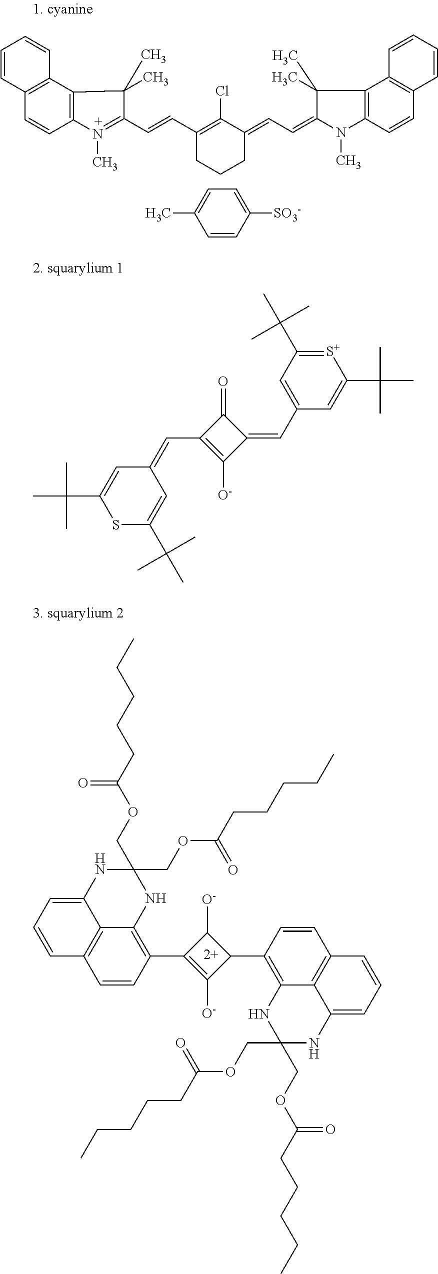

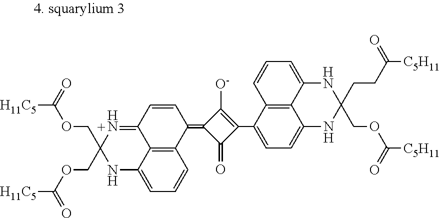

### <Acid Generating Agent>

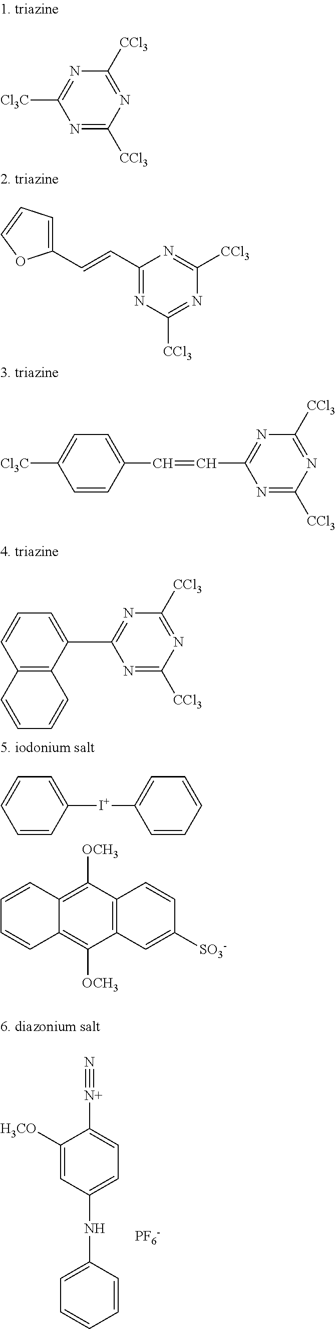

### <Colorant>

1. OIL BLUE 613 (produced by Orient Chemical Industries Co., Ltd.)
2. Victoria Pure Blue BOH-M (produced by Hodogaya Chemistry Company)

### 3 Cyanine

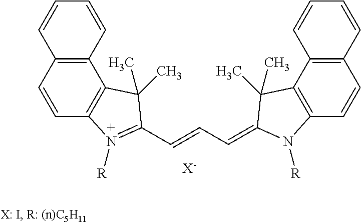

4. phthalocyanine pigment dispersed material (PGM (propylene glycol monomethyl ether) dispersion liquid with a solid content of 35% by weight)

### <Surface Active Agent>

1. fluorochemical Surfactant, Megafac F-177 (produced by DIC Corporation)
2. fluorochemical Surfactant, PF-6320 (produced by OMNOVA Corporation)

### <Production of Planography Plate Material Nos. 106 to 144>

Onto the roughened surfaces of the supports 3, respective photosensitive layer coating liquids were coated respectively by use of a wire bar so as to become a dry coated amount of 1.6 g/m2, and dried while being held for 60 seconds in a hot air circulation type drier with a temperature of 80° C. whereby Planography plate materials 106 to 144 were produced.

The glossiness of the plate surface of each of the produced planography plate materials was measured, and the measurement results are shown in Table 8.

### <Image Exposure>

The produced planography plate materials were subjected to image exposure corresponding to 175 lines at an image resolution of 2400 dpi (dpi represents the number of dots per 1 inch, i.e., 2.54 cm) with a drum rotational speed of 100 rpm while changing a laser output from 40% to 100% by a step of 5% by use of a commercially-available CTP setter with a semiconductor laser head (PTR-4300, produced by Dainippon Screen Mfg. Co., Ltd.). The exposed images include a 50% halftone image and a solid image. The laser output at exposure was set from 60.4 mJ/cm² to 160.4 mJ/cm².

<Heat Treatment after Exposure>

The planography plate materials were subjected to heat treatment immediately after exposure (within 5 minutes). In the heat treatment, Quartz Supreme Pre-bake Oven (produced by Glunz & Jensen) was used. The heat treatment conditions were adjusted to a set temperature: 275 F (135.0° C.), and retention time: 75 seconds. A plate-psurface reaching temperature was confirmed beforehand such that a thermo label was pasted on a planography plate material and the planography plate material was subjected to heat treatment. As a result, the plate-psurface reaching temperature at the time of processing was 135° C. At this time, a thermo label capable of indicating a temperature by a step of 5° C. was used.

### <Development>

The planography plate materials were subjected to development immediately after the heat treatment (less than 5 minutes). The development was conducted by use of an automatic development device: Raptor 85T (produced by Glunz & Jensen) with a developer having the following compositions. The development conditions were adjusted to a liquid temperature: 26° C., processing retention time: 25 seconds. Tap water was used in place of a gum liquid, and gum processing was not performed.

In this way, images were formed on the planography plate materials, whereby planography plates were produced.

### (Developer Composition)

TABLE 8

| Materials | Additive amount |
|---|---|
| Pure water | 85.64 |
| Potassium silicate A: 40% by weight aqueous | 8.39 |
| solution (produced by by Nippon Kagaku Co., | |
| Ltd.) | |
| Potassium hydroxide: 50% by weight aqueous | 5.84 |
| solution (produced by Toho Kagaku Co., Ltd.) | |
| Trilon M: 40% by weight aqueous solution | 0.13 |
| (produced by BASF Corp.) | |

### <Sensitivity Evaluation>

For each of Planography plate material Nos. 106 to 144, an actual halftone dot % of the 50% halftone dot image portion formed by changing the exposure output was measured by use of iCPlate 2 (produced by X-Rite Corporation) so as to produce a curve showing a change of halftone dot % to the exposure energy. From the curve, an exposure energy with which the actual halftone dot % becomes 50% was determined and was made as the 50% halftone dot sensitivity. The 50% halftone dot sensitivity of each planography plate material is shown in Table 9.

Moreover, in the case where, even with the 100% output, the actual halftone dot % of the 50% halftone dot image portion was less than 50%, the remark “low sensitivity” is shown in Table 9. Further, in the case where images were not formed under this plate making conditions, the remark “image formation failure” is shown.

### <Solvent Resistance 1>

For each of Planography plate materials No. 106 to 144, images were formed with an exposure output which was the respective halftone dot sensitivity or more and nearest to the 50% halftone dot sensitivity, and solid images were cut out from the formed images and a part of the solid images was immersed in PGM (propylene glycol monomethyl ether) so as to check the solvent resistance. In the case where, even with the 100% output, the actual halftone dot % was less than 50%, image portions with the 100% output were used. Further, in the case where, even with the 100% output, uniform solid images were not formed, this case was made as image formation failure, and the solvent resistance was not evaluated. At the time of immersion, the liquid temperature was set to 20° C., and immersion time was set to 120 minutes. In Solvent resistance 1, the solvent resistance was visually evaluated based on the following criteria, and the results are shown in Table 9. It is presumed that as the solvent resistance becomes better, the cross linking of the coating layer at image portions advances more so that the coating layer becomes tougher. Evaluation criteria of solvent resistance: As rank value is larger, the solvent resistance is better.

5: The color of the coating layer of image portions was almost not likely to change, and the border line between the immersed portion and the not-immersed portion was not conspicuous.

4: The color of the coating layer of image portions changes little, but the border line between the immersed portion and the not-immersed portion was able to be confirmed clearly.

3: The color of the coating layer of image portions changes greatly, and the optical density of the immersed portion became half of that of the not-immersed portion.

2: The color of the coating layer of image portions almost disappeared.

1: The color of the coating layer of image portions completely disappeared, and the peel-off of the coating layer took place.

### <Solvent Resistance 2>

Solvent resistance 2 was evaluated in the same way as Solvent resistance 1 except that Kinyodampclean 2 ECO (produced by Kinyo Corporation) which was a commercially-available cleaner containing diethylene glycol monobutyl ether in an amount of about 75% was employed as solvent. The results are shown in Table 9.

Coating liquid Nos. 6, and 22-44 were the samples in which the total amount of the amount of the binder and the amount of the cross linking agent was made constant, and the ratio of the cross linking agent/binder (a/b) and a ratio (A:B) of novolak resin and polyvinyl phenol polymer in the binder were changed.

TABLE 9

| Planography | | | 50% halftone dot | | | |
|---|---|---|---|---|---|---|
| plate material | Coating | Plate surface | sensitivity | Solvent | Solvent | Re- |
| No. | liquid No. | glossiness | (mJ/cm²) | resistance 1 | resistance 2 | marks |
| 106 | 6 | 20 | 135 | 5 | 5 | Inv. |
| 107 | 7 | 20 | 140 | 4 | 5 | Inv. |
| 108 | 8 | 21 | 140 | 5 | 5 | Inv. |
| 109 | 9 | 19 | 130 | 1 | 1 | Comp. |
| 110 | 10 | 19 | Low sensitivity | 2 | 3 | Comp. |
| 111 | 11 | 19 | 125 | 1 | 1 | Comp. |
| 112 | 12 | 19 | 140 | 1 | 2 | Comp. |
| 113 | 13 | 19 | Low sensitivity | 1 | 1 | Comp. |
| 114 | 14 | 19 | ** | ** | I ** | Comp. |
| 115 | 15 | 19 | 135 | 1 | 1 | Comp. |
| 116 | 16 | 19 | 140 | 2 | 3 | Comp. |
| 117 | 17 | 5 | 150 | 2 | 2 | Comp. |
| 118 | 18 | 3 | 155 | 1 | 1 | Comp. |
| 119 | 19 | 18 | 145 | 1 | 1 | Comp. |
| 120 | 20 | 20 | 130 | 1 | 1 | Comp. |
| 121 | 21 | 21 | 155 | 3 | 3 | Comp. |
| 122 | 22 | 20 | 155 | 3 | 3 | Comp. |
| 123 | 23 | 20 | 150 | 3 | 3 | Comp. |
| 124 | 24 | 20 | 140 | 4 | 5 | Inv. |
| 125 | 25 | 20 | 135 | 5 | 5 | Inv. |
| 126 | 26 | 20 | 135 | 4 | 5 | Inv. |
| 127 | 27 | 20 | 130 | 3 | 4 | Comp. |
| 128 | 28 | 20 | 135 | 3 | 3 | Comp. |
| 129 | 29 | 20 | 140 | 4 | 5 | Inv. |
| 130 | 30 | 20 | 145 | 3 | 3 | Comp. |
| 131 | 31 | 20 | 130 | 4 | 5 | Inv. |
| 132 | 32 | 20 | 130 | 3 | 3 | Comp. |
| 133 | 33 | 20 | 140 | 5 | 5 | Inv. |
| 134 | 34 | 20 | 145 | 3 | 3 | Comp. |
| 135 | 35 | 20 | 135 | 5 | 5 | Inv. |
| 136 | 36 | 20 | 140 | 2 | 3 | Comp. |
| 137 | 37 | 20 | 150 | 3 | 3 | Comp. |
| 138 | 38 | 20 | 135 | 3 | 2 | Comp. |
| 139 | 39 | 20 | 150 | 3 | 4 | Comp. |
| 140 | 40 | 20 | 130 | 3 | 3 | Comp. |
| 141 | 41 | 20 | 135 | 2 | 3 | Comp. |
| 142 | 42 | 20 | 135 | 3 | 3 | Comp. |
| 143 | 43 | 20 | ** | ** | ** | Comp. |
| 144 | 44 | 20 | 130 | 2 | 1 | Comp. |

Inv.: Inventive, Comp.: Comparative,
** Image formation failure

As can be seen from Table 9, the planography plate materials of the present invention have proper sensitivity in actual post-exposure heating conditions and exhibit excellence in solvent resistance in the formed images.

### Example 2

### Production of Planography Plate Nos. 11-15 to 11-42

Planography plate Nos. 11-15 to 11-42 were produced in the same way as that in Example 1 except that the post-exposure heating condition in heat treatment after exposure in Planography plate material Nos. 106 and 109 were changed to the conditions shown in Table 10.

At this time, the exposure condition was set to 135 mJ/cm².

### <Evaluation>

Solvent resistance (Solvent resistance 1, Solvent resistance 2) was evaluated in the same way as that in Example 1.

### <Development Remainder (Density of Non-Image Portions)>

Further, the density of the non-image portions (density of the surface of the support which appeared or came out by development) was measured as follows. In the case where the density increased 0.01 or more for the density (reference density) of the non-image portion obtained by the post-exposure heating condition A, since development remainder occurred, the development remainder was evaluated as presence. On the other hand, in the case where the density was less than 0.01, the development remainder was evaluated as absence. The results are shown in Table 11.

### <Measuring Method for Density of Non-Image Portions>

The cyan density of non-image portions on an plate surface was measured at Status T by use of X-Rite 528 (produced by X-Rite Corporation).

### <Post-Exposure Heating Condition>

The following Device 1 and Device 2 were used.

The plate-surface reaching temperature was confirmed in the same way as that in Example 1.

Device 1: Quartz Supreme Pre-bake Oven (made by Glunz & Jensen)

Device 2: A device included two consecutive heating zones which were able to set temperature independently. The two heating zones had the same length and the same retention time by conveyance through respective zones.

The post-exposure heat processing conditions A to H are shown in Table 10.

TABLE 10

| | | Heating zone | | | | | |
|---|---|---|---|---|---|---|---|
| | | First heating zone | | | Second heating zone | | Plate- |
| Post-exposure | | (leading) | | | (following) | | surface |
| heat processing | | Preset | | Processing | Preset | Processing | reaching |
| condition | Device | temperature | | time | temperature | time | temperature |
| A | 1 | 260 | F. | 60 | — | — | 125° C. |
| | | (126.7° | C.) | | | | |
| B | 1 | 280 | F. | 60 | — | — | 135° C. |
| | | (137.8° | C.) | | | | |
| C | 1 | 300 | F. | 60 | — | — | 145° C. |
| | | (148.9° | C.) | | | | |
| D | 1 | 310 | F. | 40 | — | — | 150° C. |
| | | (154.4° | C.) | | | | |
| E | 1 | 315 | F. | 40 | — | — | 155° C. |
| | | (157.2° | C.) | | | | |
| F | 1 | 325 | F. | 40 | — | — | 160° C. |
| | | (162.8° | C.) | | | | |
| G | 1 | 320 | F. | 25 | — | — | 145° C. |
| | | (160.0° | C.) | | | | |
| H | 1 | 260 | F. | 90 | — | — | 125° C. |
| | | (126.7° | C.) | | | | |
| I | 2 | 150° | C. | 20 | 130° C. | 20 | 135° C. |
| J | 2 | 155° | C. | 20 | 140° C. | 20 | 140° C. |
| K | 2 | 160° | C. | 20 | 130° C. | 20 | 145° C. |
| L | 2 | 160° | C. | 20 | 150° C. | 20 | 150° C. |
| M | 2 | 170° | C. | 20 | 150° C. | 20 | 155° C. |
| N | 2 | 140° | C. | 20 | 125° C. | 20 | 125° C. |

TABLE 11

| | | | Post- | Platte-surface | | | | |
|---|---|---|---|---|---|---|---|---|
| | Planography | | exposure | reaching | | | | |
| Planography | plate | Coating | heating | temperature | Solvent | Solvent | Development | |
| plate No. | material No. | liquid No. | condition | (° C.) | resistance 1 | resistance 2 | remainder | Remarks |
| II-15 | 106 | 6 | A | 125 | 3 | 4 | Absence | Inventive |
| II-16 | 106 | 6 | B | 135 | 5 | 5 | Absence | Inventive |
| II-17 | 106 | 6 | C | 145 | 5 | 5 | Absence | Inventive |
| II-18 | 106 | 6 | D | 150 | 5 | 5 | Absence | Inventive |
| II-19 | 106 | 6 | E | 155 | 5 | 5 | Presence | Inventive |
| II-20 | 106 | 6 | F | 160 | 5 | 5 | Presence | Inventive |
| II-21 | 106 | 6 | G | 145 | 5 | 5 | Absence | Inventive |
| II-22 | 106 | 6 | H | 125 | 3 | 4 | Absence | Inventive |
| II-23 | 106 | 6 | I | 135 | 5 | 5 | Absence | Inventive |
| II-24 | 106 | 6 | J | 140 | 5 | 5 | Absence | Inventive |
| II-25 | 106 | 6 | K | 145 | 5 | 5 | Absence | Inventive |
| II-26 | 106 | 6 | L | 150 | 5 | 5 | Absence | Inventive |
| II-27 | 106 | 6 | M | 155 | 5 | 5 | Presence | Inventive |
| II-28 | 106 | 6 | N | 125 | 3 | 4 | Absence | Inventive |
| II-29 | 109 | 9 | A | 125 | 1 | 1 | Absence | Comparative |
| II-30 | 109 | 9 | B | 135 | 1 | 1 | Absence | Comparative |
| II-31 | 109 | 9 | C | 145 | 1 | 1 | Absence | Comparative |
| II-32 | 109 | 9 | D | 150 | 1 | 2 | Absence | Comparative |
| II-33 | 109 | 9 | E | 155 | 1 | 2 | Presence | Comparative |
| II-34 | 109 | 9 | F | 160 | 1 | 3 | Presence | Comparative |
| II-35 | 109 | 9 | G | 145 | 1 | 1 | Absence | Comparative |
| II-36 | 109 | 9 | H | 125 | 1 | 1 | Absence | Comparative |
| II-37 | 109 | 9 | I | 135 | 1 | 1 | Absence | Comparative |
| II-38 | 109 | 9 | J | 140 | 1 | 1 | Absence | Comparative |
| II-39 | 109 | 9 | K | 145 | 1 | 1 | Absence | Comparative |
| II-40 | 109 | 9 | L | 150 | 1 | 2 | Absence | Comparative |
| II-41 | 109 | 9 | M | 155 | 1 | 2 | Presence | Comparative |
| II-42 | 109 | 9 | N | 125 | 1 | 1 | Absence | Comparative |

As can be seen from Table 11, the planography plate materials of the present invention has good solvent resistance in a wide range of the post-exposure heading conditions so that these plate materials have large tolerance on heat conditions. However, from the viewpoint of solvent resistance, the plate-surface reaching temperature at the time of heating after exposure is preferably set to 130° C. or more, and further, from the viewpoint of development remainder, the plate-surface reaching temperature is preferably set to less than 155° C.

On the other hand, in the planography plate materials of Comparative examples, even on the strong heating conditions which were a level to cause the development remainder, solvent resistance was almost not improved.

### Example 3

### Production of Planography plate Nos. 111 to 9 to 111 to 43

Planography plate material Nos. 301 to 323, 122 to 136 were produced in the same way as that in Example 1 except that the combination of supports, coating liquids, and coated weight by use of Nos. 6, 9, 12, 17, 22 to 36 were changed to the combinations shown in Table 12.

The following evaluation was conducted for Planography plate material Nos. 106, 109, 112, 117, 122 to 136, 301 to 323, 122 to 136.

The obtained planography plate materials were subjected to exposure, post-exposure heat treatment, development treatment, thereby forming images. The resulting images contained 5% and 50% halftone images and solid images. The energy at the time of exposure was made to the energy of the 50% halftone dot sensitivity of the planography plate materials produced by use of respective coating liquids in Example 1. Further, at the time of the development treatment, a commercially-available gum liquid was used.

### <Evaluation of Wear Resistance at the Time of Printing>

Evaluation of wear resistance at the time of printing was conducted for respective planography plate materials on which images were formed (that is, planography plate) in the following procedures.

In the evaluation, employed were as a printing device, DAIYA 1 F-1 produced by Mitsubishi Heavy Industrial Co.; as a printing sheet, OK topcoat; as a wet water, 2% by weight of Astro-mark 3 (produced by Nikken Chemicals Laboratory Company); and as an ink, TK high unity neo SOY red (produced by Toyo Ink Corporation).

Further, Plate reverse (produced by Nikken Chemicals Laboratory Company) which was a cleaner containing an abrasive compound was used as a printing plate cleaner.

First, printing of 500 sheets was conducted, and a 500^{th} printed matter was checked and evaluated by the visual observation and the magnifying lens (magnification: 30 times). No scratch was observed on the solid images on respective planography plates, and also lack of the 5% halftone dots was not observed.

Successively, plate surface cleaning was conducted in such a way that the plate surfaces of the planography plates were wiped uniformly by two round trips with a sponge into which cleaner was infiltrated and further wiped with another sponge squeezed with water so as to wipe off the remaining cleaner. Subsequently, printing of 500 sheets was conducted, and then a 500^{th} printed matter was checked and evaluated in the same way.

The above work was repeated so as to obtain the number of times of cleaning at which the lack of the 5% halftone dot image begins to occur and the number of times of cleaning at which the scratch begins to occur on the solid image. The obtained numbers of times of cleaning are shown as criteria of wear resistance in Table 12.

TABLE 12

| | | | | | | | Wear resistance | | |
|---|---|---|---|---|---|---|---|---|---|
| | | | | | | | (the number of | | |
| | Planography | Coating | | | Coating | Coating | times of cleaning) | | |
| Planography | plate | liquid | Support | Ra | weight | weight - | 5% halftone | Solid | |
| plate No. | material No. | No. | No. | (μm) | (g/m²) | Ra | dot image | image | Remarks |
| III-9 | 308 | 6 | 2 | 0.4 | 1.3 | 0.9 | 16 | 18 | Inventive |
| III-10 | 309 | 6 | 2 | 0.4 | 1.6 | 1.2 | 20 | 22 | Inventive |
| III-11 | 310 | 6 | 3 | 0.5 | 1.4 | 0.9 | 15 | 16 | Inventive |
| III-12 | 106 | 6 | 3 | 0.5 | 1.6 | 1.1 | 20 | 21 | Inventive |
| III-13 | 311 | 6 | 3 | 0.5 | 1.8 | 1.3 | 22 | 24 | Inventive |
| III-14 | 312 | 6 | 4 | 0.6 | 1.3 | 0.7 | 13 | 15 | Inventive |
| III-15 | 313 | 6 | 4 | 0.6 | 1.6 | 1 | 17 | 20 | Inventive |
| III-16 | 314 | 6 | 5 | 0.65 | 1.4 | 0.75 | 13 | 15 | Inventive |
| III-17 | 315 | 9 | 2 | 0.4 | 1.6 | 1.2 | 6 | 8 | Comparative |
| III-18 | 316 | 9 | 3 | 0.5 | 1.4 | 0.9 | 4 | 5 | Comparative |
| III-19 | 109 | 9 | 3 | 0.5 | 1.6 | 1.1 | 6 | 7 | Comparative |
| III-20 | 317 | 9 | 5 | 0.65 | 1.5 | 0.85 | 3 | 4 | Comparative |
| III-21 | 318 | 12 | 1 | 0.35 | 1.8 | 1.45 | 8 | 9 | Comparative |
| III-22 | 112 | 12 | 3 | 0.5 | 1.6 | 1.1 | 6 | 6 | Comparative |
| III-23 | 319 | 12 | 4 | 0.6 | 1.4 | 0.8 | 4 | 5 | Comparative |
| III-24 | 320 | 12 | 4 | 0.6 | 1.8 | 1.2 | 6 | 7 | Comparative |
| III-25 | 117 | 17 | 3 | 0.5 | 1.6 | 1.1 | 5 | 7 | Comparative |
| III-26 | 321 | 17 | 4 | 0.6 | 1.4 | 0.8 | 5 | 6 | Comparative |
| III-27 | 322 | 17 | 4 | 0.6 | 1.2 | 0.6 | 3 | 3 | Comparative |
| III-28 | 323 | 17 | 5 | 0.65 | 1.7 | 1.05 | 5 | 6 | Comparative |
| III-29 | 122 | 22 | 3 | 0.5 | 1.6 | 1.1 | 9 | 10 | Comparative |
| III-30 | 123 | 23 | 3 | 0.5 | 1.6 | 1.1 | 10 | 11 | Comparative |
| III-31 | 124 | 24 | 3 | 0.5 | 1.6 | 1.1 | 17 | 19 | Inventive |
| III-32 | 125 | 25 | 3 | 0.5 | 1.6 | 1.1 | 20 | 21 | Inventive |
| III-33 | 126 | 26 | 3 | 0.5 | 1.6 | 1.1 | 19 | 20 | Inventive |
| III-34 | 127 | 27 | 3 | 0.5 | 1.6 | 1.1 | 10 | 12 | Comparative |
| III-35 | 128 | 28 | 3 | 0.5 | 1.6 | 1.1 | 8 | 10 | Comparative |
| III-36 | 129 | 29 | 3 | 0.5 | 1.6 | 1.1 | 18 | 19 | Inventive |
| III-37 | 130 | 30 | 3 | 0.5 | 1.6 | 1.1 | 10 | 11 | Comparative |
| III-38 | 131 | 31 | 3 | 0.5 | 1.6 | 1.1 | 17 | 19 | Inventive |
| III-39 | 132 | 32 | 3 | 0.5 | 1.6 | 1.1 | 8 | 10 | Comparative |
| III-40 | 133 | 33 | 3 | 0,5 | 1.6 | 1.1 | 20 | 21 | Inventive |
| III-41 | 134 | 34 | 3 | 0.5 | 1.6 | 1.1 | 9 | 11 | Comparative |
| III-42 | 135 | 35 | 3 | 0.5 | 1.6 | 1.1 | 20 | 21 | Inventive |
| III-43 | 136 | 36 | 3 | 0.5 | 1.6 | 1.1 | 7 | 10 | Comparative |

As can be seen from Table 12, the planography plate materials (obtained planography plate) of the present invention have good wear resistance at image portions irrespective of the support Ra and the photosensitive later coated weight. Among them, in the case where the value of (Coated weight−Ra) was 1.0 or more, specifically, good wear resistance can be obtained.

In the planography plate material of Comparative example, even in the case where the value of (Coated weight−Ra) was made 1.0 or more, good wear resistance was not obtained.

### Example 4

### Preparation of Planography Plate Materials

Planography plate material Nos. 106, 109, 112, and 117 were used.

### <Evaluation of Chemical Resistance (Solvent Resistance) at the Time of Printing>

Evaluation of wear resistance at the time of printing was conducted for respective planography plate materials on which images were formed in the same way as that in Example 3 (that is, planography plate) in the following procedures.

As same as Example 3, in the evaluation, employed were as a printing device, DAIYA 1 F-1 produced by Mitsubishi Heavy Industrial Co.; as a printing sheet, OK topcoat; as a wet water, 2% by weight of Astro-mark 3 (produced by Nikken Chemicals Laboratory Company); and as an ink, TK high unity neo SOY red (produced by Toyo Ink Corporation).

Further, as the cleaner for blankets, Kinyodampclean 2 ECO (produced by Kinyo Corporation) was used.

First, printing of 500 sheets was conducted, and a 500^{th} printed matter was checked and evaluated by the visual observation. No scratch was observed on the solid images on respective planography plate materials (that is, planography plates) and also unevenness was not observed on the 50% halftone dots.

Successively, cleaning was conducted in such a way that the blanket surfaces of the planography plates were wiped with a sponge into which cleaner was infiltrated. Subsequently, on the condition that the cleaner on the blanket was not dried, printing of 4,500 sheets was conducted, and then the 5000^{th} printed matter was checked and evaluated in the same way.

Thereafter, the above work was repeated for each of the printing of 5000 sheets and the printing was continued until the 2000,000^{th} printed matter so as to obtain the total number of printed sheets at which unevenness begins to occur on the 50% halftone dot image and the total number of printed sheets at which the scratch begins to occur on the solid image. The obtained numbers of printed sheets are shown as criteria of chemical resistance in Table. When unevenness and scratch were not observed even in the case where 2000,000^{th} sheets were printed, the remark “2000,000^{th} sheets or more” is shown in Table.

Results are shown in Table 13.

TABLE 13

| | Planography | | | | | Chemical resistance (the | | |
|---|---|---|---|---|---|---|---|---|
| | plate | Coating | | | Coating | number of printed sheets) | | |
| Planography | material | liquid | Support | Ra | weight | 50% halftone | | Re- |
| plate No. | No. | No. | No. | (μm) | (g/m²) | point image | solid image | marks |
| III-12 | 106 | 6 | 3 | 0.5 | 1.6 | 2000,000^{th} | 2000,000^{th} | Inv. |
| | | | | | | sheets or | sheets or | |
| | | | | | | more | more | |
| III-19 | 109 | 9 | 3 | 0.5 | 1.6 | 70,000^{th} | 50,000^{th} | Comp. |
| | | | | | | sheets | sheets | |
| III-22 | 112 | 12 | 3 | 0.5 | 1.6 | 140,000^{th} | 140,000^{th} | Comp. |
| | | | | | | sheets | sheets | |
| III-25 | 117 | 17 | 3 | 0.5 | 1.6 | 110,000^{th} | 100,000^{th} | Comp. |
| | | | | | | sheets | sheets | |

Inv.: Inventive, Comp.: Comparative

As can be seen from Table 13, the planography plate materials (obtained planography plate) of the present invention have good solvent resistance. Accordingly, even in the sever printing condition that a chemical (cleaner) containing a solvent so much adheres on the plate surface, the above plate materials have very good printing resistance.

### Example 5

### Production of Support No. 6

Support 6 was produced in the same way as that in Example 1 except that a 0.20 mm thick aluminum plate (material 1050, refining H 16) was used.

### <Production of Planography Plate Material No. 501>

Planography plate material No. 501 was produced in the same way as that in Example 1 by use of Support No. 6 and Coating liquid No. 6.

Image exposure was conducted for this material in the same way as that in Example 1.

Successively, post-exposure heat treatment and development treatment were conducted based on two post-exposure heating conditions and development treatment conditions.

### <Post-Exposure Heating and Development Treatment Conditions>

Condition X: A post-exposure heat treatment device 1 and an automatic development device are connected serially so as to conduct the development treatment immediately after the heat treatment.

The heat treatment condition was made to the condition C in Example 2.

The conveyance speed of the automatic development device is made to conform to that of the heat treatment device.

The developing temperature was adjusted such that the developing condition was made to 26° C. and 25 seconds.

Condition Y: A post-exposure heat treatment device 2 and an automatic development device are connected serially so as to conduct the development treatment immediately after the heat treatment.

The heat treatment condition was made to the condition K in Example 2.

The conveyance speed of the automatic development device is made to conform to that of the heat treatment device.

The developing temperature was adjusted such that the developing condition was made to 26° C. and 25 seconds.

Solvent resistance was evaluated for the planography plate materials after the development treatment (that is for the planography plate) in the same way as that in Example 1.

The degree of deformation (deformation so-called “ripple”) of the planography plate materials due to thermal history was evaluated visually. The evaluation was made based on the following criteria.

A: Deformation was hardly observed.

B: Deformation was observed, but was a level not to influence printed images.

C: Deformation was remarkable and was a level to fear influences to printed images.

Evaluation results are shown in Table 15.

TABLE 14

| | | First zone | | | Second zone | | Plate- |
|---|---|---|---|---|---|---|---|
| Heat | | | | Processing | | Processing | surface |
| development | | Preset | | time | Preset | time | reaching |
| condition | Device | temperature | | (seconds) | temperature | (seconds) | temperature |
| X | 1 | 300 | F. | 60 | — | — | 145° C. |
| | | (148.9° | C.) | | | | |
| Y | 2 | 160° | C. | 20 | 130° C. | 20 | 145° C. |

TABLE 15

| | Planography | | | | | | |
|---|---|---|---|---|---|---|---|
| | plate | Coating | | Heat | Solvent | Solvent | Degree of |
| Planography | material | liquid | Support | development | resistance | resistance | deformation |
| plate No. | No. | No. | No. | condition | 1 | 2 | of plate |
| V-1 | 501 | 6 | 6 | X | 5 | 5 | A |
| | | | | Y | 5 | 5 | B |

As can be seen from Table 15, the planography plate materials of the present invention have good solvent resistance even in the case that the thickness of the support becomes as thin as 0.20 mm. If the thickness of the support becomes thin, there is fear about deformation of the support due to thermal history in the process of post-exposure heat treatment and development treatment. However, according to the multi-staged heating conditions (the temperature set for the last heating zone is lower than the temperature set for the previous heating zones), the deformation of the plate can be suppressed without deteriorating solvent resistance.

1-7. (canceled)

8. A planography plate material, comprising:
an aluminum support subjected to surface-roughening treatment and anodizing treatment; and
a photosensitive layer provided on the aluminum support and including a binder resin, a cross-linking agent, an infrared absorbing agent, and an acid generating agent;
wherein the binder resin contains a novolak resin containing a phenol component in an amount of 20 to 100 weight % by weight ratio and a polyvinyl phenol polymer, and a proportion (X:Y) between a weight (X) of the novolak resin and a weight (Y) of the polyvinyl phenol polymer is 7:3 to 3:7, and wherein a ratio (b/a) of a weight (b) of the cross-linking agent to a weight (a) of the binder resin is 0.25 to 0.5.

9. The planography plate material described in claim 8, wherein the cross-linking agent contains a melamine resin.

10. The planography plate material described in claim 8, wherein the acid generating agent contains a triazine compound.

11. The planography plate material described in claim 8, wherein a surface roughness Ra of the aluminum support and a dried coating weight (g/m²) of the photosensitive layer satisfy Formula (1).
Dried coating weight of a photosensitive layer−Ra=1.0 Formula (1)

12. A planography plate, comprising:
the planography plate material which is described in claim 8 and has been subjected to image exposure, heat treatment, and development treatment,
wherein a plate-surface reaching temperature at the time of heat treatment is 130 to 155° C.

13. The planography plate described in claim 12, wherein in the heat treatment, the planography plate material is conveyed sequentially through a plurality of heating zones, and the temperature of the last heating zone is lower than that of the previous heating zones.

14. The planography plate described in claim 13, wherein the temperature of the last heating zone is lower 5° C. or more than that of the previous heating zones.
